(19) United States
(12) Patent Application Publication
(10) Pub. No.: US 2025/0228064 A1
(43) Pub. Date: Jul. 10, 2025

(54) Organic Light Emitting Device and Display Apparatus

(71) Applicant: BOE Technology Group Co., Ltd., Beijing (CN)

(72) Inventors: Yang LIU, Beijing (CN); Lei CHEN, Beijing (CN); Dan WANG, Beijing (CN)

(21) Appl. No.: 18/700,286

(22) PCT Filed: Mar. 21, 2023
(86) PCT No.: PCT/CN2023/082845

§ 371 Date: Apr. 11, 2024

(51) Int. Cl. H10K 50/12; H10K 50/18; H10K 101/00; H10K 101/30; H10K 101/40

(52) U.S. Cl. CPC H10K 50/12; H10K 50/181; H10K 2101/30; H10K 2101/40; H10K 2101/90

(57) ABSTRACT

An organic light emitting device and a display apparatus. The organic light emitting device comprises an anode (100), a cathode (200) and a light emitting structure layer disposed between the anode (100) and the cathode (200). The light emitting structure layer comprises at least a first emitting layer (EML1), the first emitting layer (EML1) comprises a first P-type host material (RH-P1), a first N-type host material (RH-N1) and a first doping material (RD1), the mass ratio of the first P-type host material (RH-P1) and the first N-type host material (RH-N1) is 3:7 to 7:3, the mass of the first doping material (RD1) is 1% to 5% of the mass of the first host material, and the mass of the first host material is the sum of the masses of the first P-type host material (RH-P1) and the first N-type host material (RH-N1).

### CROSS-REFERENCE TO RELATED APPLICATION

The present application is a U.S. National Phase Entry of International Application No. PCT/CN2023/082845, having an international filing date of Mar. 21, 2023, the entire contents of which are hereby incorporated into the present application by reference.

### TECHNICAL FIELD

The present disclosure relates to, but is not limited to, the technical field of display, in particular to an organic light emitting device and a display apparatus.

### BACKGROUND

An Organic Light Emitting Device (abbreviated as an OLED) as a new type of flat panel display is gradually receiving increasing attention. An OLED is an active light emitting device, which has the advantages of high brightness, color saturation, ultra-thinness, wide angle of view, low power consumption, extremely high response speed, and flexibility.

An OLED includes an anode, a cathode, and an emitting layer disposed between the anode and the cathode. A light emitting principle of the OLED is to inject holes and electrons into the emitting layer from the anode and the cathode respectively. When the electrons and the holes meet in the emitting layer, the electrons and the holes recombine to produce excitons. When transforming from an excited state to a ground state, these excitons emit light.

### SUMMARY

The following is a summary of subject matters described herein in detail. This summary is not intended to limit the protection scope of claims.

An organic light emitting device comprises an anode, a cathode and a light emitting structure layer disposed between the anode and the cathode, the light emitting structure layer comprises at least a first emitting layer, the first emitting layer comprises a first P-type host material, a first N-type host material and a first doping material, the mass ratio of the first P-type host material to the first N-type host material is 3:7 to 7:3, the mass of the first doping material is 1% to 5% of the mass of the first host material, and the mass of the first host material is the sum of the masses of the first P-type host material and the first N-type host material.

In an exemplary implementation, the first P-type host material and the first N-type host material satisfy:

$$0.1 \leq μ e ( RH - N 1 ) / μ h ( RH - P 1 ) \leq 1000 ;$$

wherein, μe(RH-N1) is the electron mobility of the first N-type host material, and μh(RH-P1) is the hole mobility of the first P-type host material.

In an exemplary implementation, the first P-type host material and the first N-type host material satisfy:

$$0.4 eV \leq \vert HOMO ( RH - N 1 ) \vert - \vert HOMO ( RH - P 1 ) \vert \leq 1. eV ;$$

$$0.3 eV \leq \vert LUMO ( RH - N 1 ) \vert - \vert LUMO ( RH - P 1 ) \vert \leq 0.7 eV ;$$

wherein, HOMO(RH-N1) is the HOMO energy level of the first N-type host material, HOMO(RH-P1) is the HOMO energy level of the first P-type host material, LUMO(RH-N1) is the LUMO energy level of the first N-type host material, and LUMO(RH-P1) is the LUMO energy level of the first P-type host material.

In an exemplary implementation, the first P-type host material and the first doping material satisfy:

$$0.2 eV \leq \vert HOMO ( RH - P 1 ) \vert - \vert HOMO ( RD 1 ) \vert \leq 0.5 eV ;$$

$$0.2 eV \leq T 1 ( RH - P 1 ) - T 1 ( RD 1 ) \leq 0.5 eV ;$$

wherein, HOMO(RH-P1) is the HOMO energy level of the first P-type host material, HOMO(RD1) is the HOMO energy level of the first doping material, T1(RH-P1) is the lowest triplet energy level of the first P-type host material, and T1(RD1) is the lowest triplet energy level of the first doping material.

In an exemplary implementation, the first N-type host material and the first doping material satisfy:

$$0.2 eV \leq \vert LUMO ( RD 1 ) \vert - \vert LUMO ( RH - N 1 ) \vert \leq 0.5 eV ;$$

$$0.2 eV \leq T 1 ( RH - N 1 ) - T 1 ( RD 1 ) \leq 0.5 eV ;$$

wherein, LUMO(RH-N1) is the LUMO energy level of the first N-type host material, LUMO(RD1) is the LUMO energy level of the first doping material, T1(RH-N1) is the lowest triplet energy level of the first N-type host material, and T1(RD1) is the lowest triplet energy level of the first doping material.

In an exemplary implementation, the light emitting structure layer further comprises a first electron block layer disposed between the anode and the first emitting layer, and the first P-type host material and the first electron block layer satisfy:

$$0 \leq \vert HOMO ( EBL 1 ) \vert - \vert HOMO ( RH - P 1 ) \vert \leq 0.3 eV ;$$

$$0.1 \leq μ h ( RH - P 1 ) / μ h ( EBL 1 ) \leq 100 ;$$

wherein, HOMO(EBL1) is the HOMO energy level of the first electron block layer, HOMO(RH-P1) is the HOMO energy level of the first P-type host material, μh(RH-P1) is the hole mobility of the first P-type host material, and μh(EBL1) is the hole mobility of the first electron block layer.

In an exemplary implementation, the first doping material and the first electron block layer satisfy:

$$0.1 eV \leq T 1 ( EBL 1 ) - T 1 ( RD 1 ) \leq 0.5 eV ;$$

wherein, T1(EBL1) is the lowest triplet energy level of the first electron block layer, and T1(RD1) is the lowest triplet energy level of the first doping material.

In an exemplary implementation, the light emitting structure layer further comprises a first hole injection layer disposed between the anode and the first electron block layer, and the first hole injection layer and the first electron block layer satisfy:

$$0 \leq \vert HOMO ( EBL 1 ) \vert - \vert HOMO ( HIL 1 ) \vert \leq 0.3 eV ;$$

$$0.1 \leq μ h ( HIL 1 ) / μ h ( EBL 1 ) \leq 100 ;$$

wherein, HOMO(HIL1) is the HOMO energy level of the first hole injection layer, and μh(HIL1) is the hole mobility of the first hole injection layer.

In an exemplary implementation, the first hole injection layer comprises a hole host material and a hole doping material, and the mass of the hole doping material is 1.5% to 4.5% of the mass of the hole host material.

In an exemplary implementation, the light emitting structure layer further comprises a charge generation layer and a second emitting layer, the first emitting layer is disposed between the anode and the charge generation layer, and the second emitting layer is disposed between the charge generation layer and the cathode; the second emitting layer comprises a second P-type host material, a second N-type host material and a second doping material, the mass ratio of the second P-type host material to the second N-type host material is 3:7 to 7:3, the mass of the second doping material is 1% to 5% of the mass of the second host material, and the mass of the second host material is the sum of the masses of the second P-type host material and the second N-type host material.

In an exemplary implementation, the second P-type host material and the second N-type host material satisfy:

$$0.1 \leq μ e ( RH - N 2 ) / μ h ( RH - P 2 ) \leq 1 \; 000 ;$$

wherein, μe(RH-N2) is the electron mobility of the second N-type host material, and μh(RH-P2) is the hole mobility of the second P-type host material.

In an exemplary implementation, the second P-type host material and the second N-type host material satisfy:

$$0.4 eV \leq \vert HOMO ( RH - N 2 ) \vert - \vert HOMO ( RH - P 2 ) \vert \leq 1. eV ;$$

$$0.3 eV \leq \vert LUMO ( RH - N 2 ) \vert - \vert LUMO ( RH - P 2 ) \vert \leq 0.7 eV ;$$

wherein, HOMO(RH-N2) is the HOMO energy level of the second N-type host material, HOMO(RH-P2) is the HOMO energy level of the second P-type host material, LUMO(RH-N2) is the LUMO energy level of the second N-type host material, and LUMO(RH-P2) is the LUMO energy level of the second P-type host material.

In an exemplary implementation, the second P-type host material, the second N-type host material, and the second doping material satisfy:

$$0.2 eV \leq \vert HOMO ( RH - P 2 ) \vert - \vert HOMO ( RD 2 ) \vert \leq 0.5 eV ;$$

$$0.2 eV \leq \vert LUMO ( RD 2 ) \vert - \vert LUMO ( RH - N 2 ) \vert \leq 0.5 eV ;$$

wherein, HOMO(RH-P2) is the HOMO energy level of the second P-type host material, HOMO(RD2) is the HOMO energy level of the second doping material, LUMO(RH-N2) is the LUMO energy level of the second N-type host material, and LUMO(RD2) is the LUMO energy level of the second doping material.

In an exemplary implementation, the first P-type host material and the second P-type host material satisfy:

$$1 \leq μ h ( RH - P 2 ) / μ h ( RH - P 1 ) \leq 100 ;$$

wherein, μh(RH-P1) is the hole mobility of the first P-type host material, and μh(RH-P2) is the hole mobility of the second P-type host material.

In an exemplary implementation, the first N-type host material and the second N-type host material satisfy:

$$1 \leq μ e ( RH - N 1 ) / μ e ( RH - N 2 ) \leq 100 ;$$

wherein, μe(RH-N1) is the electron mobility of the first N-type host material, and μe(RH-N2) is the electron mobility of the second N-type host material.

In an exemplary implementation, the first P-type host material and the second P-type host material satisfy:

$$HOMO ( RH - P 1 ) \leq HOMO ( RH - P 2 ) ;$$

wherein, HOMO(RH-P1) is the HOMO energy level of the first P-type host material, and HOMO(RH-P2) is the HOMO energy level of the second P-type host material.

In an exemplary implementation, the first N-type host material and the second N-type host material satisfy:

$$LUMO ( RH - N 1 ) \leq LUMO ( RH - N 2 ) ;$$

wherein, LUMO(RH-N1) is the LUMO energy level of the first N-type host material, and LUMO(RH-N2) is the LUMO energy level of the second N-type host material.

In an exemplary implementation, the first emitting layer and the second emitting layer satisfy:

$$10 \leq μ e ( EML 1 ) / μ h ( EML 1 ) \leq 5000 ;$$

$$10 \leq μ e ( EML 2 ) / μ h ( EML 2 ) \leq 5000 ;$$

$$1 \leq μ h ( EML 2 ) / μ h ( EML 1 ) \leq 100 ;$$

$$1 \leq μ e ( EML 1 ) / μ e ( EML 2 ) \leq 100 ;$$

wherein, μe(EML1) is the electron mobility of the first emitting layer, μe(EML2) is the electron mobility of the second emitting layer, μh(EML1) is the hole mobility of the first emitting layer, and μh(EML2) is the hole mobility of the second emitting layer.

In an exemplary implementation, the light emitting structure layer further comprises a first electron block layer disposed between the anode and the first emitting layer and a second electron block layer disposed between the charge generation layer and the second emitting layer, and the first electron block layer and the second electron block layer satisfy:

$$1 \leq μ h ( EBL 2 ) / μ h ( EBL 1 ) \leq 100 ;$$

wherein, μh(EBL1) is the hole mobility of the first electron block layer, and μh(EBL2) is the hole mobility of the second electron block layer.

In an exemplary implementation, the first electron block layer, the first emitting layer, the second electron block layer, and the second emitting layer satisfy:

$$HOMO ( RH - N 1 ) < HOMO ( EBL 1 ) < HOMO ( RH - P 1 ) ;$$

$$HOMO ( RH - N 2 ) < HOMO ( EBL 2 ) < HOMO ( RH - P 2 ) ;$$

wherein, HOMO(RH-N1) and HOMO(RH-N2) are the HOMO energy levels of the first N-type host material and the second N-type host material, respectively, HOMO(RH-P1) and HOMO(RH-P2) are the HOMO energy levels of the first P-type host material and the second P-type host material, respectively, and HOMO(EBL1) and HOMO(EBL2) are the HOMO energy levels of the first electron block layer and the second electron block layer, respectively.

In an exemplary implementation, the first electron block layer, the first emitting layer, the second electron block layer, and the second emitting layer satisfy:

$$T 1 ( RD 1 ) < T 1 ( RH - P 1 ) < T 1 ( EBL 1 ) ;$$

$$T 1 ( RD 2 ) < T 1 ( RH - P 2 ) < T 1 ( EBL 2 ) ;$$

$$T 1 ( RD 1 ) < T 1 ( RH - N 1 ) < T 1 ( EBL 1 ) ;$$

$$T 1 ( RD 2 ) < T 1 ( RH - N 2 ) < T 1 ( EBL 2 ) ;$$

wherein, T1(RH-N1) and T1(RH-N2) are the lowest triplet energy levels of the first N-type host material and the second N-type host material, respectively, T1(RH-P1) and T1(RH-P2) are the lowest triplet energy levels of the first P-type host material and the second P-type host material, respectively, T1(RD1) and T1 (RD2) are the lowest triplet energy levels of the first doping material and the second doping material, respectively, and T1(EBL1) and T1(EBL2) are the lowest triplet energy levels of the first electron block layer and the second electron block layer, respectively.

A display apparatus includes the aforementioned organic light emitting device.

Other aspects of the present disclosure may be comprehended after the drawings and the detailed descriptions are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display apparatus.

FIG. 2 is a schematic diagram of the planar structure of a plurality of sub-pixels in a display apparatus.

FIG. 3 is a schematic diagram of the sectional structure of sub-pixels in a display apparatus.

FIG. 4 is a schematic diagram of an OLED structure according to an exemplary embodiment of the present disclosure.

FIG. 5 is a schematic diagram of another OLED structure according to an exemplary embodiment of the present disclosure.

FIG. 6 is a schematic diagram of yet another OLED structure according to an exemplary embodiment of the present disclosure.

FIG. 7 is a schematic diagram of yet another OLED structure according to an exemplary embodiment of the present disclosure.

FIG. 8 is a schematic diagram of yet another OLED structure according to an exemplary embodiment of the present disclosure.

FIG. 9 is a schematic diagram of yet another OLED structure according to an exemplary embodiment of the present disclosure.

FIG. 10 is a comparison result of efficiency curves of structure 5, comparative structure 2 and comparative structure 3.

FIG. 11A, FIG. 11B, and FIG. 11C illustrate schematic diagrams of exciton recombination regions of structure 5, comparative structure 2, and comparative structure 3, respectively.

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, “parallel” refers to a state in which an angle formed by two straight lines is −10° or more and 100 or less, and thus also includes a state in which the angle is −5° or more and 5° or less. In addition, “perpendicular” refers to a state in which an angle formed by two straight lines is 800 or more and 1000 or less, and thus also includes a state in which the angle is 850 or more and 950 or less.

“About” herein refers to that a boundary is defined not so strictly and numerical values within process and measurement error ranges are allowed.

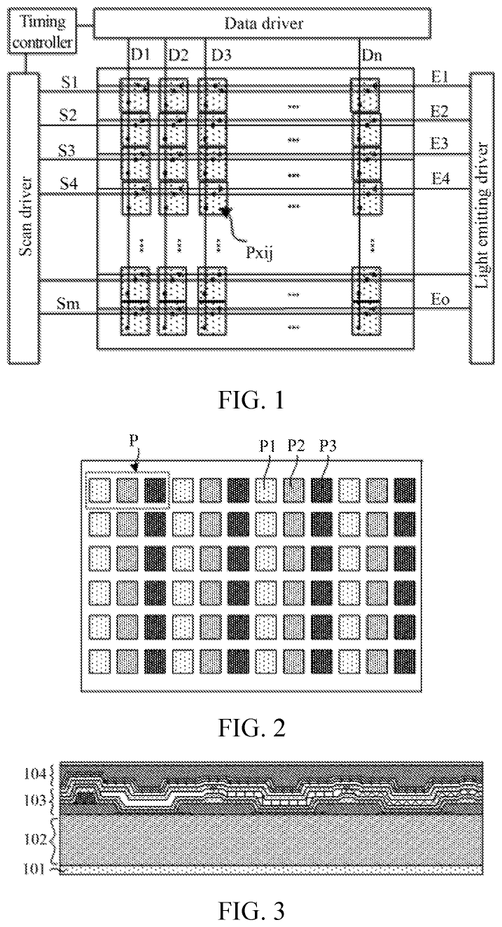

FIG. 1 is a schematic diagram of a structure of a display apparatus. As shown in FIG. 1, the display apparatus may include a timing controller, a data driver, a scan driver, a light emitting driver and a pixel array. The timing controller is connected with the data driver, the scan driver and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. n, m, and o can be natural numbers. The pixel array may include a plurality of sub-pixels Pxij, wherein i and j may be natural numbers. At least one sub-pixel Pxij may include a circuit unit and a light emitting device connected with the circuit unit, wherein the circuit unit may include a pixel drive circuit which is connected with a scan signal line, a data signal line, and a light emitting signal line, respectively. In an exemplary implementation, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value by using a clock signal, and apply a data voltage corresponding to the gray scale value to the data signal lines D1 to Dn by taking a pixel column as a unit. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal by sequentially transmitting a scan starting signal provided in a form of an on-level pulse to a next stage circuit under control of the clock signal. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of the shift register, and generate an emission signal by sequentially transmitting an emission stopping signal provided in the form of an off-level pulse to a next-stage circuit under the control of the clock signal.

FIG. 2 is a schematic diagram of the planar structure of a plurality of sub-pixels in a display apparatus. As shown in FIG. 2, a plurality of sub-pixels may include a first sub-pixel P1 emitting light of a first color, a second sub-pixel P2 emitting light of a second color, and a third sub-pixel P3 emitting light of a third color, the first sub-pixel P1, the second sub-pixel P2, and the third sub-pixel P3 each includes a pixel drive circuit and a light emitting device. Pixel drive circuits in the first sub-pixel P1, the second sub-pixel P2, and the third sub-pixel P3 are connected with a scan signal line, a data signal line, and a light emitting signal line respectively. A pixel drive circuit is configured to receive a data voltage transmitted by the data signal line under control of the scan signal line and the light emitting signal line, and output a corresponding current to the light emitting device. Light emitting devices in the first sub-pixel P1, the second sub-pixel P2, and the third sub-pixel P3 are respectively connected with the pixel drive circuit of the sub-pixel in which the light emitting device is located, and the light emitting device is configured to emit light with a corresponding brightness in response to a current outputted by the pixel drive circuit of the sub-pixel in which the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged side by side horizontally, side by side vertically, or in a manner like a Chinese character “ [symbol] ”, the present disclosure is not limited thereto.

In other exemplary implementation, a plurality of sub-pixels may include four sub-pixels, which may be arranged side by side horizontally, side by side vertically, or in a shape of a square, the present disclosure is not limited thereto.

FIG. 3 is a schematic diagram of the sectional structure of sub-pixels in a display apparatus, illustrating structures of three sub-pixels. As shown in FIG. 3, a sub-pixel may include a drive structure 102 disposed on the substrate 101, an organic light emitting device 103 disposed on a side of the drive structure 102 away from the substrate 101, and an encapsulation structure 104 disposed on a side of the organic light emitting device 103 away from the substrate 101. In some possible implementations, the sub-pixels may include other structures such as touch structures and the like which are not limited herein.

In an exemplary implementation, the substrate 101 may be a flexible substrate, or may be a rigid substrate. The driving structure 102 may include a plurality of transistors and storage capacitors constituting a pixel driving circuit. The organic light emitting device 103 may include an anode connected with the drain electrode of the driving transistor through a via hole, a light emitting structure layer connected with the anode, and a cathode connected with the light emitting structure layer, and the light emitting structure layer emits light of a corresponding color under driving of the anode and the cathode. The encapsulation structure 104 may include a first encapsulation layer, a second encapsulation layer, and a third encapsulation layer that are stacked. The first encapsulation layer and the third encapsulation layer may adopt inorganic materials, and the second encapsulation layer may adopt an organic material. The second encapsulation layer is disposed between the first encapsulation layer and the third encapsulation layer, which may ensure that external water vapor cannot enter the light emitting structure layer.

In an exemplary implementation, the light emitting structure layer may include an Emitting Layer (EML) and any one or more of the following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, one or more of hole injection layers, hole transport layers, electron block layers, hole block layers, electron transport layers and electron injection layers of all sub-pixels may be connected together to form a common connected layer. The emitting layers of adjacent sub-pixels may overlap slightly with each other, or may be isolated from each other.

In an exemplary implementation, the light emitting structure layer may be prepared and formed through evaporation using a Fine Metal Mask (FMM) or an open mask, or prepared and formed using an ink-jet process.

With the continuous development of products, the market requires higher resolution of products, higher brightness of independent sub-pixels and lower power consumption of products. Therefore, higher requirements are attached to the efficiency, brightness, voltage and service life of the device. Research shows that in single-layer OLED devices, because the electron mobility of the emitting layer is greater than the hole mobility, the exciton recombination region is close to the electron block layer, and the exciton recombination region is narrow, which leads to triplet exciton annihilation (TTA) and triplet exciton-polaron quenching (TPQ), and then leads to a large efficiency roll-off at high current density, which reduces the efficiency of light emitting devices at high current density. In tandem OLED devices, due to the imbalance of the injection and transport of holes and electrons between different emitting layers, large efficiency roll-off occurs at high current density. Because the efficiency roll-off trends of red light-emitting devices, blue light-emitting devices and green light-emitting devices are not consistent, the white balance of the display apparatus is not consistent under the working voltage and the turn-on voltage which degrades the display quality.

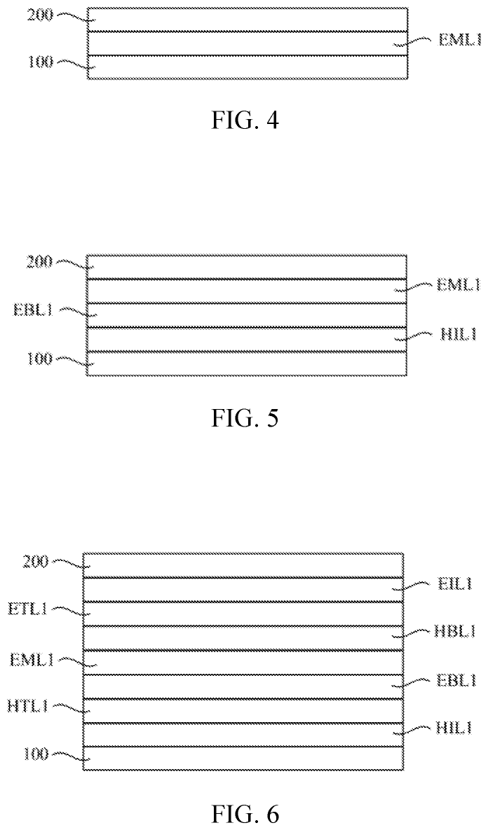

FIG. 4 is a schematic diagram of an OLED structure according to an exemplary embodiment of the present disclosure. As shown in FIG. 4, the OLED includes an anode 100, a cathode 200, and an emitting structure layer disposed between the anode 100 and the cathode 200. In an exemplary implementation, the light emitting structure layer may include a first emitting layer EML1 configured to cause recombination of electrons and holes to emit light.

In an exemplary implementation, the first emitting layer EML1 may include a first P-type host material RH-P1 and a first N-type host material RH-N1 as host materials, and a first doping material RD1 as a guest material. The first P-type host material RH-P1 may be referred to as the first hole transport host material, and the first N-type host material RH-N1 may be referred to as the first electron transport host material.

In an exemplary implementation, the mass ratio of the first P-type host material RH-P1 and the first N-type host material RH-N1 may be about 3:7 to 7:3.

In some exemplary implementations, the mass ratio of the first P-type host material RH-P1 and the first N-type host material RH-N1 may be about 4:6 to 6:4. In some other exemplary implementations, the mass ratio of the first P-type host material RH-P1 and the first N-type host material RH-N1 may be about 5:5.

In an exemplary implementation, the mass of the first doping material RD1 may be about 1% to 5% of the total mass of the first host material, and the total mass of the first host material is the sum of the masses of the first P-type host material RH-P1 and the first N-type host material RH-N1, i.e. the first doping ratio may be about 1% to 5%. The doping ratio refers to a ratio of the mass of the guest material to the mass of the host material, that is, the mass percentage. By setting the range of doping ratio described above, on one hand, the host material can efficiently transfer exciton energy to the guest material to excite the guest material to emit light, and on the other hand, the guest material is diluted by the host material, which effectively improve intermolecular collision of the guest material and fluorescence quenching caused by the mutual collision of energy, improve the light emitting efficiency, and prolong the service life of the device.

In an exemplary implementation, the first P-type host material RH-P1, the first N-type host material RH-N1 and the first doping material RD1 may be co-evaporated through a multi-source evaporation process, so that the first P-type host material RH-P1, the first N-type host material RH-N1 and the first doping material RD1 are uniformly dispersed in the first emitting layer, and the mixing ratio and the doping ratio may be regulated by controlling the evaporation rates of the first P-type host material RH-P1, the first N-type host material RH-N1 and the first doping material RD1 during the evaporation process.

In an exemplary implementation, the first P-type host material RH-P1 and the first N-type host material RH-N1 may satisfy:

$$0.1 \leq μ e ( RH - N 1 ) / μ h ( RH - P 1 ) \leq 1000 .$$

In the exemplary implementation, μe(RH-N1) is the electron mobility of the first N-type host material RH-N1, which is the intrinsic mobility of the N-type host material, and μh(RH-P1) is the hole mobility of the first P-type host material RH-P1, which is the intrinsic mobility of the P-type host material.

In an exemplary implementation, the first P-type host material RH-P1 and the first N-type host material RH-N1 may satisfy:

$$0.4 eV \leq \vert HOMO ( RH - N 1 ) \vert - \vert HOMO ( RH - P 1 ) \vert \leq 1. eV ;$$

$$0.3 eV \leq \vert LUMO ( RH - N 1 ) \vert - \vert LUMO ( RH - P 1 ) \vert \leq 0.7 Ev .$$

In the exemplary implementation, HOMO(RH-N1) is the Highest Occupied Molecular Orbital (HOMO) energy level of the first N-type host material RH-N1, HOMO(RH-P1) is the HOMO energy level of the first P-type host material RH-P1, LUMO(RH-N1) is the Lowest Unoccupied Molecular Orbital (LUMO) energy level of the first N-type host material RH-N1, and LUMO(RH-P1) is the LUMO energy level of the first P-type host material RH-P1.

In an exemplary implementation, the first P-type host material RH-P1 and the first doping material RD1 may satisfy:

$$0.2 eV \leq \vert HOMO ( RH - P 1 ) \vert - \vert HOMO ( RD 1 ) \vert \leq 0.5 eV .$$

In the exemplary implementation, HOMO(RD1) is the HOMO energy level of the first doping material RD1.

In an exemplary implementation, the first P-type host material RH-P1 and the first doping material RD1 may satisfy:

$$0.2 eV \leq T 1 ( RH - P 1 ) - T 1 ( RD 1 ) \leq 0.5 eV .$$

In the exemplary implementation, T1(RH-P1) is the lowest triplet energy level of the first P-type host material RH-P1, and T1(RD1) is the lowest triplet energy level of the first doping material RD1.

In an exemplary implementation, the first N-type host material RH-N1 and the first doping material RD1 may satisfy:

$$0.2 \leq \vert LUMO ( RD 1 ) \vert - \vert LUMO ( RH - N 1 ) \vert \leq 0.5 eV .$$

In the exemplary implementation, LUMO(RD1) is the LUMO energy level of the first doping material RD1.

In an exemplary implementation, the first N-type host material RH-N1 and the first doping material RD1 may satisfy:

$$0.2 eV \leq T 1 ( RH - N 1 ) - T 1 ( RD 1 ) \leq 0.5 eV .$$

In the exemplary implementation, T1(RH-N1) is the lowest triplet energy level of the first N-type host material RH-N1.

In an exemplary implementation, a first P-type host material RH-P1 may include, but is not limited to, compounds having structures shown in Formula 1-1:

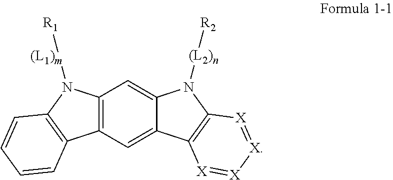

In Formula 1-1, L1 and L2 are each independently selected from benzene, biphenyl or naphthalene, m and n are each independently 0 or 1, R1 and R2 are each independently selected from benzene, naphthalene, triphenylene, dibenzofuran, dibenzothiophene, dimethylfluorene, diphenylfluorene or spirofluorene, X is independently carbon C or N, and two adjacent Xs can form a ring to form the structures of Formula 1-2 and Formula 1-3.

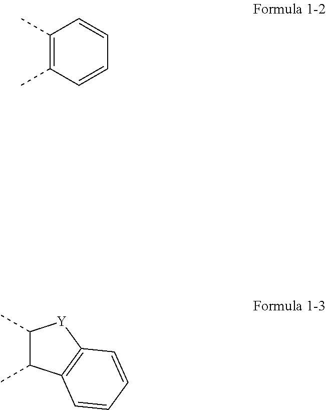

In Formula 1-3, Y is O, S or NR3.

In an exemplary implementation, a first N-type host material RH-N1 may include, but is not limited to, compounds having structures shown in Formula 2-1:

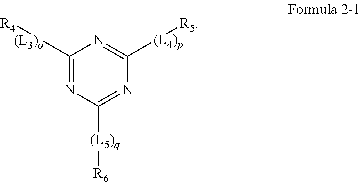

In Formula 2-1, L3, L4 and L5 are each independently selected from benzene, biphenyl and naphthalene, o, p and q are each independently 0 or 1, and R4, R5 and R6 are each independently selected from benzene, naphthalene, triphenylene, dibenzofuran, benzodibenzofuran, dibenzothiophene, benzodibenzothiophene, dimethylfluorene, diphenylfluorene, spirofluorene, spiroxanthene, Formula 2-2, Formula 2-3 or Formula 2-4.

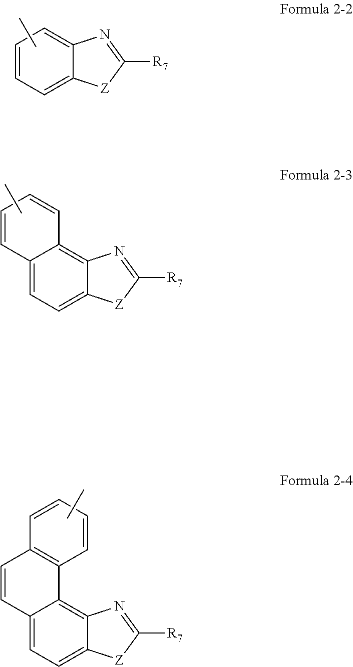

In Formula 2-2 to Formula 2-4, R7 is independently selected from benzene, biphenyl, naphthalene, alkyl having 1-6 carbons and cycloalkyl, and Z is independently selected from O, S and NR8.

In an exemplary implementation, a first doping material RD1 may include, but is not limited to, compounds having structures shown in Formula 3-1:

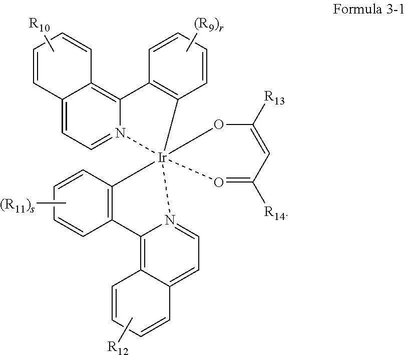

In Formula 3-1, R9-R14 are each independently selected from alkyl having 1-6 carbons or cycloalkyl, and r and s are each independently selected from 0, 1, 2, 3, 4.

FIG. 5 is a schematic diagram of another OLED structure according to an exemplary embodiment of the present disclosure. As shown in FIG. 5, the OLED includes an anode 100, a cathode 200, and a light emitting structure layer disposed between the anode 100 and the cathode 200. In an exemplary implementation, the light emitting structure layer may include a first hole injection layer HIL1, a first electron block layer EBL1 and a first emitting layer EML1 that are stacked. The first hole injection layer HIL1 and the first electron block layer EBL1 are disposed between the anode 100 and the first emitting layer EML1, and the first electron block layer EBL1 is disposed between the first hole injection layer HIL1 and the first emitting layer EML1. In an exemplary implementation, the first hole injection layer HIL1 is configured to lower the barrier of injecting holes from the anode, so that the holes can be effectively injected into the first emitting layer from the anode. The first electron block layer EBL1 is configured to form a migration barrier for electrons to prevent electrons from migrating out of the first emitting layer EML1.

In an exemplary implementation, the first emitting layer may adopt the materials, energy level relationships and mobility relationships of the foregoing embodiments.

In an exemplary implementation, the first P-type host material RH-P1 and the first electron block layer EBL1 may satisfy:

$$0 \leq \vert HOMO ( EBL 1 ) \vert - \vert HOMO ( RH - P 1 ) \vert \leq 0.3 eV ;$$

$$0.1 \leq μ h ( RH - P 1 ) / μ h ( EBL 1 ) \leq 10 \; 0 .$$

In the exemplary implementation, HOMO(EBL1) is the HOMO energy level of the first electron block layer EBL1, and μh(EBL1) is the hole mobility of the first electron block layer EBL1.

In an exemplary implementation, the first doping material RD1 and the first electron block layer EBL1 may satisfy:

$$0.1 eV \leq T 1 ( EBL 1 ) - T 1 ( RD 1 ) \leq 0.5 eV .$$

In the exemplary implementation, T1(EBL1) is the lowest triplet energy level of the first electron block layer EBL1.

In an exemplary implementation, the first electron block layer EBL1 and the first hole injection layer HIL1 may satisfy:

$$0 \leq \vert HOMO ( EBL 1 ) \vert - \vert HOMO ( HIL 1 ) \vert \leq 0.3 eV ;$$

$$0.1 \leq μ h ( HIL 1 ) / μ h ( EBL 1 ) \leq 10 \; 0 .$$

In the exemplary implementation, HOMO(HIL1) is the HOMO energy level of the first hole injection layer HIL1, and μh(HIL1) is the hole mobility of the first hole injection layer HIL1.

In an exemplary implementation, the first hole injection layer HIL1 may include a hole host material HT and a hole doping material PD, the mass of which may be about 1.5% to 4.5% of the mass of the hole host material HT, i.e. the doping ratio of the hole doping material PD may be about 1.5% to 4.5%.

In an exemplary implementation, the first electron block layer EBL1 may include, but is not limited to, a compound having a structure shown in Formula 4-1:

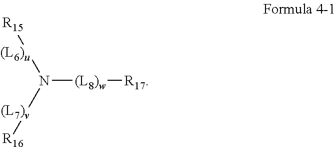

In Formula 4-1, L6, L7 and L8 are each independently benzene, biphenyl and naphthalene, u, v and w are each independently 0 or 1, and R15, R16 and R17 are each independently optionally substituted carbazole, dibenzofuran, dibenzothiophene, dimethylfluorene, diphenylfluorene, spirofluorene, adamantane or spiroxanthene.

In an exemplary implementation, the hole host material HT in the first hole injection layer HIL1 may include, but is not limited to, a compound having a structure shown in Formula 5-1:

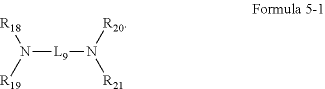

In Formula 5-1, L9 is independently benzene, biphenyl, naphthalene, dibenzofuran and dibenzothiophene, and R18, R19, R20 and R21 are each independently optionally substituted benzene, biphenyl, naphthalene, dibenzofuran, dibenzothiophene, dimethylfluorene or diphenylfluorene.

In an exemplary implementation, the hole doping material PD in the first hole injection layer HIL1 may include, but is not limited to, a compound having a structure shown in Formula 6-1:

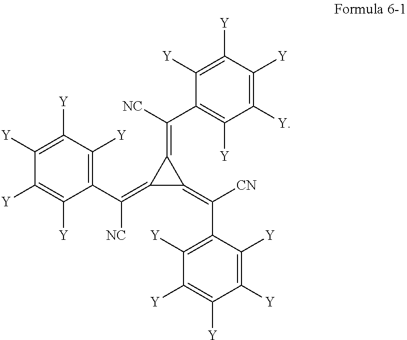

In Formula 6-1, Y is independently the group of fluorine or cyano.

In an exemplary implementation, the first emitting layer may be a red emitting layer.

FIG. 6 is a schematic diagram of yet another OLED structure according to an exemplary embodiment of the present disclosure. As shown in FIG. 6, the OLED includes an anode 100, a cathode 200, and a light emitting structure layer disposed between the anode 100 and the cathode 200. In an exemplary implementation, the light emitting structure layer may include a first hole injection layer HIL1, a first hole transport layer HTL1, a first electron block layer EBL1, a first emitting layer EML1, a first hole block layer HBL1, a first electron transport layer ETL1, and a first electron injection layer EIL1 that are stacked. A first hole injection layer HIL1, a first hole transport layer HTL1, and a first electron block layer EBL1 may be disposed between the anode 100 and the first emitting layer EML1. The first hole injection layer HIL1 is connected with the Anode 100, the first electron block layer EBL1 is connected with the first emitting layer EML1, and the first hole transport layer HTL1 is disposed between the first hole injection layer HIL1 and the first electron block layer EBL1. A first hole block layer HBL1, a first electron transport layer ETL1, and a first electron injection layer EIL1 may be disposed between the first emitting layer EML1 and the cathode 200. The first hole block layer HBL1 is connected with the first emitting layer EML1, the first electron injection layer EIL1 is connected with the cathode 200 and the first electron transport layer ETL1 is disposed between the first hole block layer HBL1 and the first electron injection layer EIL1. In an exemplary implementation, the first hole transport layer HTL1 is configured to realize directed and ordered controllable migration of injected holes. The first hole block layer HBL1 is configured to form a migration barrier for holes to prevent holes from migrating out of the first emitting layer EML1. The first electron transport layer ETL1 is configured to realize directed and ordered controllable migration of injected electrons. The first electron injection layer EIL1 is configured to lower the barrier of injecting electrons from the cathode so that electrons can be effectively injected from the cathode to the first emitting layer EML1.

In an exemplary implementation, the first hole injection layer, the first electron block layer and the first emitting layer may adopt the materials, energy level relationships and mobility relationships of the foregoing embodiments.

In an exemplary implementation, the anode may adopt a material having a high work function. For a bottom emitting type, the anode may adopt a transparent oxide material such as indium tin oxide (ITO) or indium zinc oxide (IZO), and a thickness of the anode may be 80 nm to 200 nm. For a top emitting type, the anode may adopt a composite structure of metal and transparent oxide, such as Ag/ITO, Ag/IZO or ITO/Ag/ITO. The thickness of the metal layer in the anode may be about 80 nm to 100 nm, and the thickness of the transparent oxide in the anode may be about 5 nm to 20 nm, so that the average reflectivity of the anode in the visible region is about 85%-95%.

In an exemplary implementation, for a top emitting type OLED, the cathode may adopt a metal material and formed by adopting an evaporation process, the metal material may be magnesium (Mg), silver (Ag) or aluminum (Al), or an alloy material, such as Mg:Ag alloy, the Mg:Ag ratio is about 9:1 to 1:9, and the thickness of the cathode may be about 10 nm to 20 nm, so that the average transmittance of the cathode at the wavelength of 530 nm is about 50%-60%. For a bottom emitting type OLED, the cathode may adopt magnesium (Mg), silver (Ag), aluminum (Al) or Mg:Ag alloy, and the thickness of the cathode may be greater than 80 nm, so that the cathode has good reflectivity.

In an exemplary implementation, the first hole transport layer may adopt an aromatic amine or carbazole material with hole transport properties, such as 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluorene-9-yl) triphenylamine (BAFLP), 4,4′-bis[N-(9,9-dimethylfluorene-2-yl)-N-phenylamino]biphenyl (DFLDPBi), 4,4′-bis(9-carbazole) biphenyl (CBP) or 9-phenyl-3-[4-(10-phenyl-9-anthracyl)phenyl]-9H-carbazole (PCzPA), etc.

In an exemplary implementation, the first electron transport layer and the first hole block layer may adopt aromatic heterocyclic compounds, such as imidazole derivatives like benzimidazole derivatives, imidazopyridine derivatives, and benzimidazophenanthridine derivatives; azine derivatives like pyrimidine derivatives and triazine derivatives; quinoline derivatives, isoquinoline derivatives, phenanthroline derivatives, compounds having a nitrogen-containing six-membered ring structure (including compounds having a phosphine oxide-based substituent on the heterocyclic ring), etc. For example, 2-(4-biphenyl)-5-(4-tert-butylphenyl)-1,3,4-oxadiazole (PBD), 1,3-bis [5-(p-tert-butylphenyl)-1,3,4-oxadiazol-2-yl]benzene (OXD-7), 3-(4-tert-butylphenyl)-4-phenyl-5-(4-biphenyl)-1,2,4-triazole (TAZ), 3-(4-tert-butylphenyl)-4-(4-ethylphenyl)-5-(4-biphenyl)-1,2,4-triazole (p-EtTAZ), red phenanthroline (BPhen), and bathocuproine (BCP) or 4,4′-bis(5-methylbenzoxazol-2-yl) stilbene (BzOs).

In an exemplary implementation, a first electron injection layer may adopt an alkali metal or a metal, such as Lithium Fluoride (LiF), Ytterbium (Yb), Magnesium (Mg), or Calcium (Ca), or a compound of these alkali metals or metals.

In an exemplary implementation, for a top emitting type OLED, a thickness of the light emitting structure layer between the cathode and the anode may be designed to meet a requirement on an optical path of an optical micro-resonator, so as to obtain optimal light output intensity and color.

In an exemplary implementation, the following preparation method may be used to prepare a display substrate including an OLED structure. First, a driving structure is formed on a substrate through a patterning process. The driving structure of each sub-pixel may include a driving transistor and a storage capacitor that form a pixel driving circuit. Then, a planarization layer is formed on the substrate on which the foregoing structures are formed, and a via hole exposing a drain electrode of the driving transistor is formed on the planarization layer of each sub-pixel. Then, an anode is formed through a patterning process on the substrate on which the foregoing structures are formed. The anode of each sub-pixel is connected with the drain electrode of the driving transistor through the via hole on the planarization layer. Then, a pixel definition layer is formed through a patterning process on the substrate on which the foregoing structures are formed. A pixel opening exposing the anode is formed in the pixel definition layer of each sub-pixel. Each pixel opening serves as a light emitting area of a corresponding sub-pixel. Then, a hole injection layer and a hole transport layer are evaporated subsequently by using an open mask on the substrate on which the above structure is formed, and a common connected layer of the hole injection layer and the hole transport layer is formed on the display substrate, that is, the hole injection layers of all sub-pixels are connected, and the hole transport layers of all sub-pixels are connected. For example, respective areas of the hole injection layer and the hole transport layer are approximately the same, but their thicknesses are different. Then, the electronic block layer and the red emitting layer, the electronic block layer and the green emitting layer, and the electronic block layer and the blue emitting layer are formed respectively by evaporation in different sub-pixels using the fine metal mask. There may be slight overlap between the electron block layers and the emitting layers of the adjacent sub-pixels (for example, the overlap portion accounts for less than 10% of the area of pattern of the respective emitting layer), or the electron block layers may be isolated from the emitting layers. Then, a hole block layer, an electron transport layer, an electron injection layer and a cathode are evaporated subsequently by using an open mask, and a common connected layer of the hole block layer, the electron transport layer, the electron injection layer and the cathode is formed on the display substrate, that is, the hole block layers of all sub-pixels are connected, the electron transport layers of all sub-pixels are connected, the electron injection layers of all sub-pixels are connected, and the cathodes of all sub-pixels are connected.

In an exemplary implementation, the orthographic projections of one or more of the hole injection layer, the hole transport layer, the hole block layer, the electron transport layer, the electron injection layer, and the cathode on the substrate are continuous. In some examples, at least one of the hole injection layer, the hole transport layer, the hole block layer, the electron transport layer, the electron injection layer, and the cathode of at least one row or column of sub-pixels is communicated. In some examples, at least one of the hole injection layer, the hole transport layer, the hole block layer, the electron transport layer, the electron injection layer, and the cathode of multiple sub-pixels is communicated.

In an exemplary implementation, the light emitting structure layer may include a micro-cavity adjustment layer located between the hole transport layer and the emitting layer. For example, after the hole transport layer is formed, a red micro-cavity adjustment layer and a red emitting layer, a green micro-cavity adjustment layer and a green emitting layer, and a blue micro-cavity adjustment layer and a blue emitting layer are respectively evaporated at different sub-pixels by using a fine metal mask. In an exemplary implementation, the red micro-cavity adjustment layer, the green micro-cavity adjustment layer, and the blue micro-cavity adjustment layer may include an electron block layer.

By setting the mass ratio of the P-type host material and the N-type host material and the doping ratio of the doping material in the emitting layer, setting the mobility relationships and the energy level relationships of the P-type host material, the N-type host material and the doping material, and setting the mobility relationships and the energy level relationships of the emitting layer, the hole injection layer and the electron block layer, the exemplary embodiments of the present disclosure can make the exciton recombination region move from the side close to the electron block layer to the center of the emitting layer, make the exciton recombination region of the emitting layer more balanced, reduce the triplet exciton annihilation and triplet exciton-polaron quenching effects, and further reduce the efficiency roll-off, which can not only improve the display brightness, but also can prolong the working life. By reducing the efficiency roll-off of red light-emitting devices, the exemplary embodiments of the present disclosure can improve the consistency of the efficiency roll-off trends of red light-emitting devices, blue light-emitting devices and green light-emitting devices, which ensure the consistency of the white balance of the display apparatus under the working voltage and the turn-on voltage, and improve the display quality.

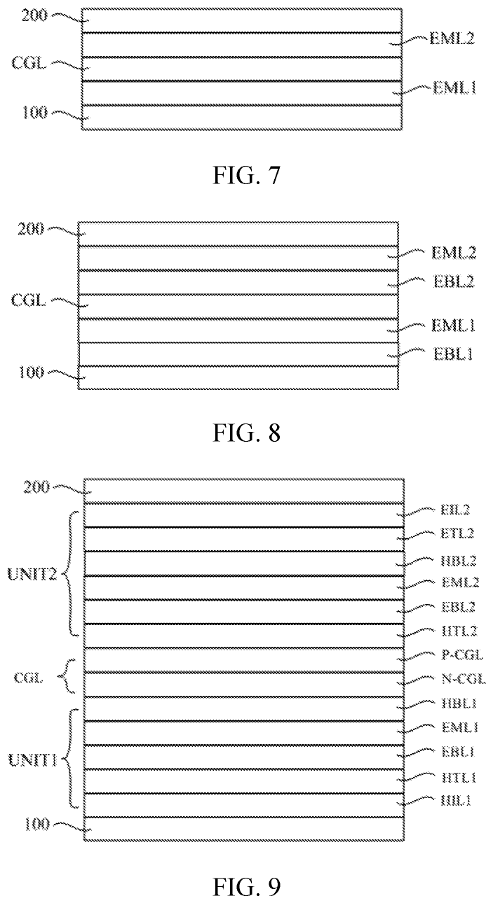

FIG. 7 is a schematic diagram of yet another OLED structure according to an exemplary embodiment of the present disclosure. As shown in FIG. 7, the OLED includes an anode 100, a cathode 200, and a light emitting structure layer disposed between the anode 100 and the cathode 200. In an exemplary implementation, the light emitting structure layer may include a first emitting layer EML1, a charge generation layer CGL, and a second emitting layer EML2 that are stacked. The first emitting layer EML1 is disposed between the anode 100 and the charge generation layer CGL. The second emitting layer EML2 is disposed between the cathode 200 and the charge generation layer CGL to constitute a tandem OLED structure, which is a high-efficiency OLED structure formed by stacking two or more emitting layers in series with each other through a connection layer. The first emitting layer EML1 and the second emitting layer EML2 are configured to recombine electrons and holes to emit light, and are separated by a charge generation layer CGL.

In an exemplary implementation, the charge generation layer CGL may include a electron generation layer N-CGL and a hole generation layer P-CGL that are stacked. The electron generation layer N-CGL may be disposed on a side of the hole generation layer P-CGL close to the anode 100 and the hole generation layer P-CGL may be disposed on a side of the electron generation layer N-CGL close to the cathode 200.

In an exemplary implementation, the first emitting layer EML1 may include a first P-type host material RH-P1 and a first N-type host material RH-N1 as host materials, and a first doping material RD1 as guest materials. The first P-type host material RH-P1, the first N-type host material RH-N1 and the first doping material RD1 may adopt the materials, energy level relationships and mobility relationships of the foregoing embodiments.

In an exemplary implementation, the second emitting layer EML2 may include a second P-type host material RH-P2 and a second N-type host material RH-N2 as host materials, and a second doping material RD2 as a guest material. The second P-type host material RH-P2 may be referred to as the second hole transport host material, and the second N-type host material RH-N2 may be referred to as the second electron transport host material.

In an exemplary implementation, the mass ratio of the second P-type host material RH-P2 and the second N-type host material RH-N2 may be about 3:7 to 7:3.

In some exemplary embodiments, the mass ratio of the second P-type host material RH-P2 and the second N-type host material RH-N2 may be about 4:6 to 6:4. In some other exemplary implementations, the mass ratio of the second P-type host material RH-P2 and the second N-type host material RH-N2 may be about 5:5.

In an exemplary implementation, the mass of the second doping material RD2 may be about 1% to 5% of the total mass of the second host material, and the total mass of the second host material is the sum of the masses of the second P-type host material RH-P2 and the second N-type host material RH-N2, i.e. the second doping ratio may be about 1% to 5%.

In an exemplary implementation, the second P-type host material RH-P2, the second N-type host material RH-N2 and the second doping material RD2 may be co-evaporated through a multi-source evaporation process, so that the second P-type host material RH-P2, the second N-type host material RH-N2 and the second doping material RD2 are uniformly dispersed in the second emitting layer, and the mixing ratio and the doping ratio may be regulated by controlling the evaporation rates of the second P-type host material RH-P2, the second N-type host material RH-N2 and the second doping material RD2 during the evaporation process.

In an exemplary implementation, the second P-type host material RH-P2 and the second N-type host material RH-N2 may satisfy:

$$0.1 \leq μ e ( RH - N 2 ) / μ h ( RH - P 2 ) \leq 1000 .$$

In the exemplary implementation, μe(RH-N2) is the electron mobility of the second N-type host material RH-N2, which is the intrinsic mobility of the N-type host material, and μh(RH-P2) is the hole mobility of the second P-type host material RH-P2, which is the intrinsic mobility of the P-type host material.

In an exemplary implementation, the second P-type host material RH-P2 and the second N-type host material RH-N2 may satisfy:

$$0.4 eV \leq \vert HOMO ( R H - N 2 ) \vert - \vert HOMO ( R H - P 2 ) \vert \leq 1. eV ;$$

$$0.3 eV \leq \vert LUMO ( R H - N 2 ) \vert - \vert LUMO ( R H - P 2 ) \vert \leq 0.7 eV .$$

In the exemplary implementation, HOMO(RH-N2) is the HOMO energy level of the second N-type host material RH-N2, HOMO(RH-P2) is the HOMO energy level of the second P-type host material RH-P2, LUMO(RH-N2) is the LUMO energy level of the second N-type host material RH-N2, and LUMO(RH-P2) is the LUMO energy level of the second P-type host material RH-P2.

In an exemplary implementation, the second P-type host material RH-P2 and the second doping material RD2 may satisfy:

$$0.2 eV \leq \vert HOMO ( R H - P 2 ) \vert - \vert HOMO ( RD 2 ) \vert \leq 0.5 eV .$$

In the exemplary implementation, HOMO(RD2) is the HOMO energy level of the second doping material RD2.

In an exemplary implementation, the second N-type host material RH-N2 and the second doping material RD2 may satisfy:

$$0.2 eV \leq \vert LUMO ( RD 2 ) \vert - \vert LUMO ( R H - N 2 ) \vert \leq 0.5 eV .$$

In the exemplary implementation, LUMO(RD2) is the LUMO energy level of the second doping material RD2.

In an exemplary implementation, the first P-type host material RH-P1 and the second P-type host material RH-P2 may satisfy:

$$1 \leq μ h ( RH - P 2 ) / μ h ( RH - P 1 ) \leq 100 .$$

In an exemplary implementation, the first N-type host material RH-N1 and the second N-type host material RH-N2 may satisfy:

$$1 \leq μ e ( RH - N 1 ) / μ e ( RH - N 2 ) \leq 100 .$$

In an exemplary implementation, the first P-type host material RH-P1 and the second P-type host material RH-P2 may satisfy:

$$HOMO ( RH - P 1 ) \leq HOMO ( RH - P 2 ) .$$

In an exemplary implementation, the first N-type host material RH-N1 and the second N-type host material RH-N2 may satisfy:

$$LUMO ( RH - N 1 ) \leq LUMO ( RH - N 2 ) .$$

In an exemplary implementation, the mass ratio of the first P-type host material RH-P1 and the first N-type host material RH-N1 in the first emitting layer EML1 is m1/n1, and the first doping ratio is x1. The mass ratio of the second P-type host material RH-P2 and the second N-type host material RH-N2 in the second emitting layer EML2 is m2/n2, the second doping ratio is x2, and 3/7≤m1/n1≤7/3, 3/7≤m2/n2≤7/3, 1%≤x1≤5%, and 1%≤x2≤5%. The first emitting layer EML1 and the second emitting layer EML2 may satisfy:

$$10 \leq μ e ( EML 1 ) / μ h ( EML 1 ) \leq 5 \; 000 ;$$

$$10 \leq μ e ( EML 2 ) / μ h ( EML 2 ) \leq 5 \; 000 ;$$

$$1 \leq μ h ( EML 2 ) / μ h ( EML 1 ) \leq 100 ;$$

$$1 \leq μ e ( EML 1 ) / μ e ( EML 2 ) \leq 100 .$$

In the exemplary implementation, μh(EML1) is the hole mobility of the first emitting layer EML1, μh(EML2) is the hole mobility of the second emitting layer EML2, μe(EML1) is the electron mobility of the first emitting layer EML1, and μe(EML2) is the electron mobility of the second emitting layer EML2.

In an exemplary implementation, the capability of generating hole charges of the hole generation layer P-CGL is weak due to its own reasons. By setting the hole mobility of the second emitting layer greater than that of the first emitting layer and the electron mobility of the first emitting layer greater than that of the second emitting layer, the present disclosure can make the hole mobility of the second emitting layer faster and the electron mobility slower, and can effectively compensate the problem of weak capability of generating hole charges of the hole generation layer P-CGL.

FIG. 8 is a schematic diagram of yet another OLED structure according to an exemplary embodiment of the present disclosure. As shown in FIG. 8, the OLED includes an anode 100, a cathode 200, and a light emitting structure layer disposed between the anode 100 and the cathode 200. In an exemplary implementation, the light emitting structure layer may include a first electron block layer EBL1, a first emitting layer EML1, a charge generation layer CGL, a second electron block layer EBL2 and a second emitting layer EML2 that are stacked. The first electron block layer EBL1 and the first emitting layer EML1 are disposed between the anode 100 and the charge generation layer CGL80, the second electron block layer EBL2 and the second emitting layer EML2 are disposed between the cathode 200 and the charge generation layer CGL, the first electron block layer EBL1 is disposed between the anode 100 and the first emitting layer EML1, and the second electron block layer EBL2 is disposed between the charge generation layer CGL and the second emitting layer EML2.

In an exemplary implementation, the first emitting layer EML1 and the second emitting layer EML2 may adopt the materials, energy level relationships and mobility relationships of the foregoing embodiments.

In an exemplary implementation, the first electron block layer EBL1 and the second electron block layer EBL2 may satisfy:

$$1 \leq μ h ( EBL 2 ) / μ h ( EBL 1 ) \leq 100.$$

In the exemplary implementation, μh(EBL1) is the hole mobility of the first electron block layer EBL1, and μh(EBL2) is the hole mobility of the second electron block layer EBL2.

In an exemplary implementation, the first electron block layer EBL1, the first emitting layer EML1, the second electron block layer EBL2, and the second emitting layer EML2 may satisfy:

$$HOMO ( RH - N 1 ) < HOMO ( EBL 1 ) < HOMO ( RH - P 1 ) ;$$

$$HOMO ( RH - N 2 ) < HOMO ( EBL 2 ) < HOMO ( RH - P 2 ) .$$

In the exemplary implementation, HOMO(RH-N1) and HOMO(RH-N2) are the HOMO energy levels of the first N-type host material RH-N1 and the second N-type host material RH-N2, respectively, HOMO(RH-P1) and HOMO(RH-P2) are the HOMO energy levels of the first P-type host material RH-P1 and the second P-type host material RH-P2, respectively, and HOMO(EBL1) and HOMO(EBL2) are the HOMO energy levels of the first electron block layer EBL1 and the second electron block layer EBL2, respectively.

In an exemplary implementation, the first electron block layer EBL1, the first emitting layer EML1, the second electron block layer EBL2, and the second emitting layer EML2 may satisfy:

$$T 1 ( RD 1 ) < T 1 ( RH - P 1 ) < T 1 ( EBL 1 ) ;$$

$$T 1 ( RD 2 ) < T 1 ( RH - P 2 ) < T 1 ( EBL 2 ) ;$$

$$T 1 ( RD 1 ) < T 1 ( RH - N 1 ) < T 1 ( EBL 1 ) ;$$

$$T 1 ( RD 2 ) < T 1 ( RH - N 2 ) < T 1 ( EBL 2 ) .$$

In the exemplary implementation, T1(RH-N1) and T1(RH-N2) are the lowest triplet energy levels of the first N-type host material RH-N1 and the second N-type host material RH-N2, respectively, T1(RH-P1) and T1(RH-P2) are the lowest triplet energy levels of the first P-type host material RH-P1 and the second P-type host material RH-P2, respectively, T1(RD1) and T1 (RD2) are the lowest triplet energy levels of the first doping material RD1 and the second doping material RD2, respectively, and T1(EBL1) and T1(EBL2) are the lowest triplet energy levels of the first electron block layer EBL1 and the second electron block layer EBL2, respectively.

In an exemplary implementation, a second P-type host material RH-P2 may include, but is not limited to, compounds having structures shown in Formula 1-1:

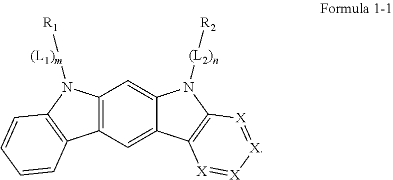

In Formula 1-1, L1 and L2 are each independently selected from benzene, biphenyl or naphthalene, m and n are each independently 0 or 1, R1 and R2 are each independently selected from benzene, naphthalene, triphenylene, dibenzofuran, dibenzothiophene, dimethylfluorene, diphenylfluorene or spirofluorene, X is independently carbon C or N, and two adjacent Xs can form a ring to form the structures of Formula 1-2 and Formula 1-3.

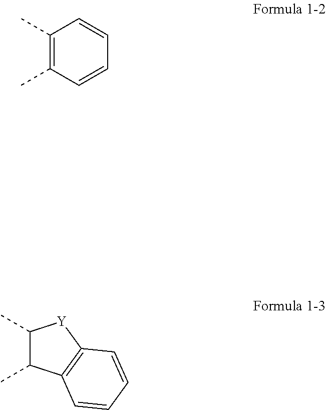

In Formula 1-3, Y is O, S or NR3.

In an exemplary implementation, a second N-type host material RH-N2 may include, but is not limited to, compounds having structures shown in Formula 2-1:

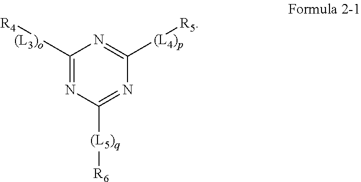

In Formula 2-1, L3, L4 and L5 are each independently selected from benzene, biphenyl and naphthalene, o, p and q are each independently 0 or 1, and R4, R5 and R6 are each independently selected from benzene, naphthalene, triphenylene, dibenzofuran, benzodibenzofuran, dibenzothiophene, benzodibenzothiophene, dimethylfluorene, diphenylfluorene, spirofluorene, spiroxanthene, Formula 2-2, Formula 2-3 or Formula 2-4.

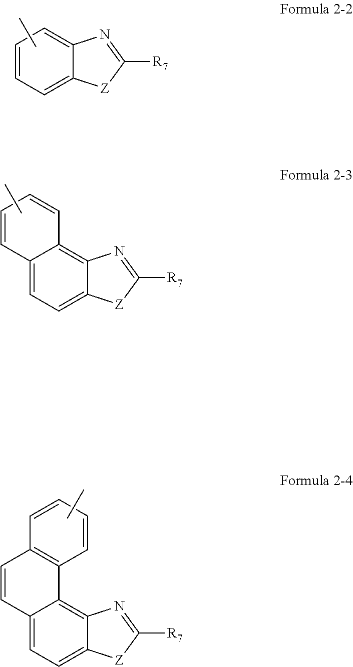

In Formula 2-2 to Formula 2-4, R7 is independently selected from benzene, biphenyl, naphthalene, alkyl having 1-6 carbons and cycloalkyl, and Z is independently selected from O, S and NR8.

In an exemplary implementation, a second doping material RD2 may include, but is not limited to, compounds having structures shown in Formula 3-1:

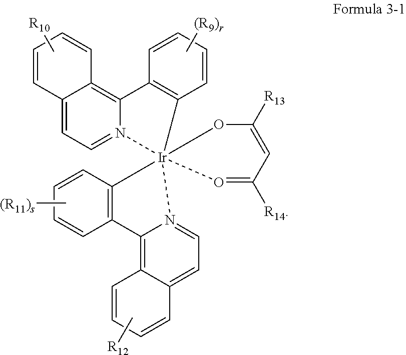

In Formula 3-1, R9-R14 are each independently selected from alkyl having 1-6 carbons or cycloalkyl, and r and s are each independently selected from 0, 1, 2, 3, 4.

In an exemplary implementation, the second electron block layer EBL2 may include, but is not limited to, a compound having a structure shown in Formula 4-1:

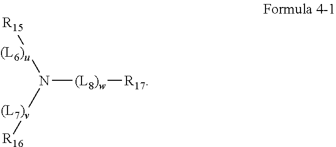

In Formula 4-1, L6, L7 and L8 are each independently benzene, biphenyl and naphthalene, u, v and w are each independently 0 or 1, and R15, R16 and R17 are each independently optionally substituted carbazole, dibenzofuran, dibenzothiophene, dimethylfluorene, diphenylfluorene, spirofluorene, adamantane or spiroxanthene.

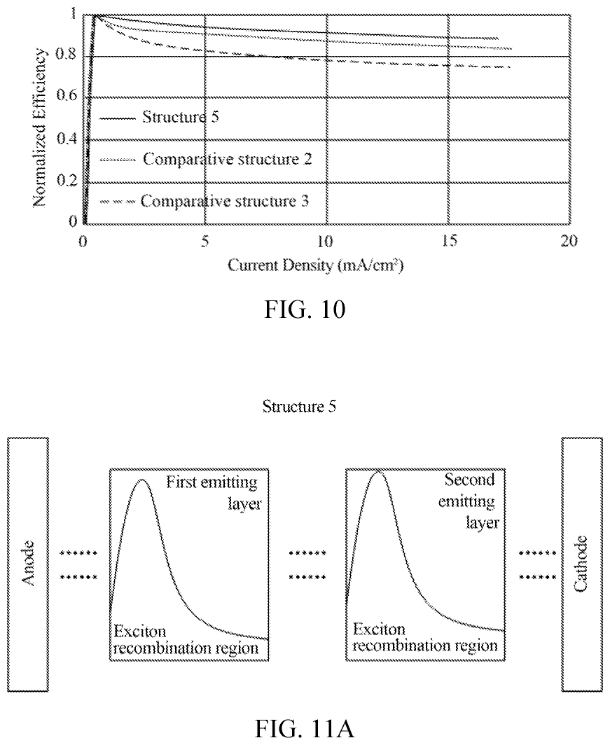

FIG. 9 is a schematic diagram of yet another OLED structure according to an exemplary embodiment of the present disclosure. As shown in FIG. 9, the OLED includes an anode 100, a cathode 200, and a light emitting structure layer disposed between the anode 100 and the cathode 200. In an exemplary implementation, the light emitting structure layer may include a first light emitting unit UNIT1, a charge generation layer CGL, and a first light emitting unit UNIT2, that are stacked, to constitute a tandem OLED structure.

In an exemplary implementation, the first light emitting unit UNIT1 may include a first hole injection layer HIL1, a first hole transport layer HTL1, a first electron block layer EBL1, a first emitting layer EML1, and a first hole block layer HBL1 that are stacked. A first hole injection layer HIL1, a first hole transport layer HTL1, and a first electron block layer EBL1 are disposed between the anode 100 and the first emitting layer EML1. The first hole injection layer HIL1 is connected with the anode 100, the first electron block layer EBL1 is connected with the first emitting layer EML1, the first hole transport layer HTL1 is disposed between the first hole injection layer HIL1 and the first electron block layer EBL1, and the first hole block layer HBL1 is disposed between the first emitting layer EML1 and the charge generation layer CGL.

In an exemplary implementation, the second light emitting unit UNIT2 may include a second hole transport layer HTL2, a second electron block layer EBL2, a second emitting layer EML2, a second hole block layer HBL2, a second electron transport layer ETL2, and a second electron injection layer EIL2 that are stacked. A second hole transport layer HTL2 and a second electron block layer EBL2 are disposed between the charge generation layer CGL and the second emitting layer EML2. The second hole transport layer HTL2 is connected with the charge generation layer CGL and the second electron block layer EBL2 is connected with the second emitting layer EML2. A second hole block layer HBL2, a second electron transport layer ETL2, and a second electron injection layer EIL2 are disposed between the second emitting layer EML2 and the cathode 200. The second hole block layer HBL2 is connected with the second emitting layer EML2, the second electron injection layer EIL2 is connected with the cathode 200 and the second electron transport layer ETL2 is disposed between the second hole block layer HBL2 and the second electron injection layer EIL2.

In an exemplary implementation, the charge generation layer CGL may include a electron generation layer N-CGL and a hole generation layer P-CGL that are stacked. The electron generation layer N-CGL is connected with the hole generation layer P-CGL, the first hole block layer HBL1 is connected with the electron generation layer N-CGL, and the second hole transport layer HTL2 is connected with the hole generation layer P-CGL.

In some possible implementations, the charge generation layer CGL may adopt a single-layer structure or may adopt a multi-layer structure of more than two layers, which is not limited here in the present disclosure.

In an exemplary implementation, the first emitting layer EML1, the second emitting layer EML2, the first electron block layer EBL1, and the second electron block layer EBL2 may adopt the materials, energy level relationships, and mobility relationships of the foregoing embodiments.

In an exemplary implementation, the first emitting layer and the second emitting layer may be a red emitting layer, or may be a green emitting layer, or may be a blue emitting layer.

By setting the mass ratios of the P-type host material and the N-type host material and the doping ratios of the doping material in the first emitting layer and the second emitting layer, setting the mobility relationships and the energy level relationships of the P-type host material, the N-type host material and the doping material, setting the mobility relationship and the energy level relationship of the first emitting layer and the second emitting layer, and setting the mobility relationship and the energy level relationship of the emitting layer and the electron block layer, the exemplary embodiments of the present disclosure effectively improve the hole-electron balance in different emitting layers, and reduce the efficiency roll-off, which can not only improve the display brightness, but also can prolong the working life.

Table 1 shows the materials of a hole injection layer, an electron block layer, and an emitting layer in a comparative experiment of an exemplary embodiment of the present disclosure. In this comparative experiment, the light emitting structure layers of structure 1 to structure 4 and comparative structure 1 all adopt the structure shown in FIG. 6, which is HIL1/HTL1/EBL1/EML1/HBL1/ETL1/EIL1, and the corresponding film layers have the same thickness.

TABLE 1

| | First hole | | First | |
|---|---|---|---|---|
| | injection layer | | electron | |
| | PD | Host | block | |
| | ratio | material | layer | First emitting layer |
| Structure 1 | 3% | HT-1 | EBL-1 | RH-P1:RH-N1(4:6):RD1(2%) |
| Structure 2 | 1.5% | HT-1 | EBL-1 | RH-P1:RH-N1(4:6):RD1(2%) |
| Structure 3 | 3% | HT-1 | EBL-1 | RH-P1:RH-N1(5:5):RD1(2%) |
| Structure 4 | 3% | HT-1 | EBL-1 | RH-P1:RH-N1(4:6):RD1(4%) |
| Comparative | 1% | HT-2 | EBL-2 | RH-P2:RH- |
| structure 1 | | | | N2(2.5:7.5):RD1(6%) |

As shown in Table 1, a first hole host material HT-1 is used as the host material in the first hole injection layer of structure 1 to structure 4, and the doping ratios of the hole doping material PD are 1.5% and 3%, respectively. A second hole host material HT-2 is used as the host material in the first hole injection layer of comparative structure 1, and the doping ratio of the hole doping material PD is 1% respectively. EBL-1 is used as the material of the first electron block layer in structure 1 to structure 4, and EBL-2 is used as the material of the first electron block layer in comparative structure 1. The mass ratios of the first P-type host material RH-P1 and the first N-type host material RH-N1 in the first emitting layers of structure 1 to structure 4 are 4:6, 4:6, 5:5 and 4:6, respectively, and the doping ratios of the first doping material RD1 are 2%, 2%, 2% and 4%, respectively. The mass ratio of the second P-type host material RH-P2 and the second N-type host material RH-N2 in the first emitting layer of comparative structure 1 is 2.5:7.5, and the doping ratio of the first doping material RD1 is 6%, respectively.

The materials of the hole injection layer, the electron block layer and the emitting layer in structure 1 to structure 4 and comparative structure 1 are respectively:

| Items | Materials |
|---|---|
| First P-type host material RH-P1 | 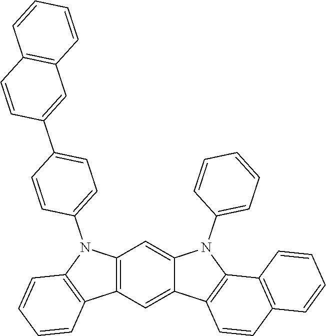 [SMILES: c1ccc(-n2c3cc4c(cc3c3ccc5ccccc5c32)c2ccccc2n4-c2ccc(-c3ccc4ccccc4c3)cc2)cc1] |
| First N-type host material RH-N1 | 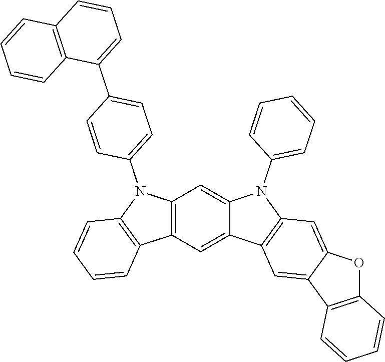 [SMILES: c1ccc(-n2c3cc4oc5ccccc5c4cc3c3cc4c5ccccc5n(-c5ccc(-c6cccc7ccccc67)cc5)c4cc32)cc1] |
| Second P-type host material RH-P2 | 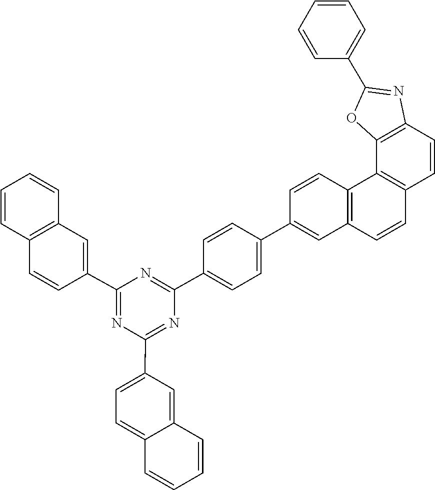 [SMILES: c1ccc(-c2nc3ccc4ccc5cc(-c6ccc(-c7nc(-c8ccc9ccccc9c8)nc(-c8ccc9ccccc9c8)n7)cc6)ccc5c4c3o2)cc1] |
| Second N-type host material RH-N2 | 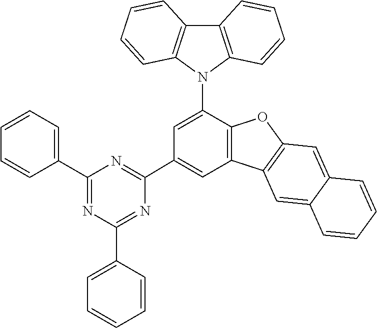 [SMILES: c1ccc(-c2nc(-c3ccccc3)nc(-c3cc(-n4c5ccccc5c5ccccc54)c4oc5cc6ccccc6cc5c4c3)n2)cc1] |
| First doping material RD1 | 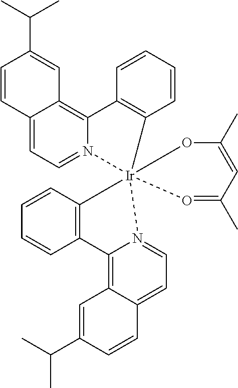 |
| First electron block layer EBL1 | 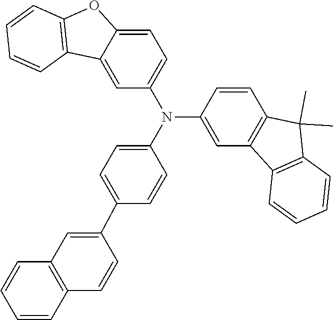 [SMILES: CC1(C)c2ccccc2-c2cc(N(c3ccc(-c4ccc5ccccc5c4)cc3)c3ccc4oc5ccccc5c4c3)ccc21] |
| Second electron block layer EBL2 | 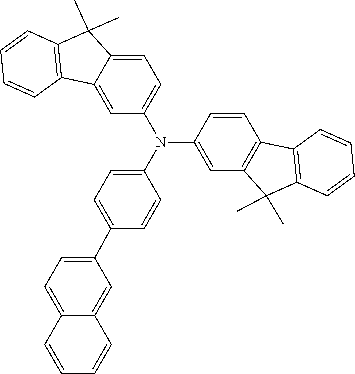 [SMILES: CC1(C)c2ccccc2-c2cc(N(c3ccc(-c4ccc5ccccc5c4)cc3)c3ccc4c(c3)C(C)(C)c3ccccc3-4)ccc21] |
| First hole host material HT-1 | 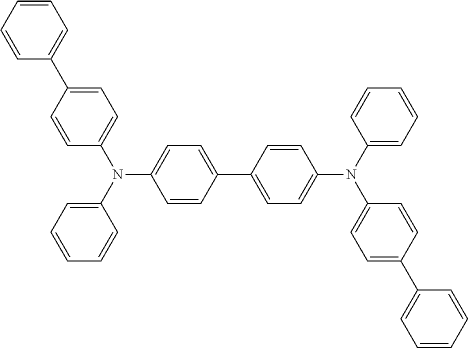 [SMILES: c1ccc(-c2ccc(N(c3ccccc3)c3ccc(-c4ccc(N(c5ccccc5)c5ccc(-c6ccccc6)cc5)cc4)cc3)cc2)cc1] |
| Second hole host material HT-2 | 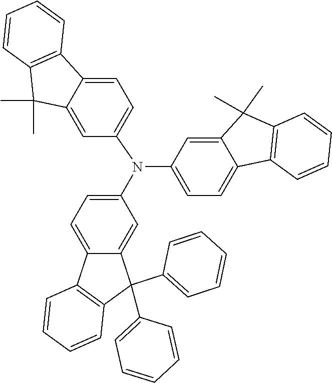 [SMILES: CC1(C)c2ccccc2-c2ccc(N(c3ccc4c(c3)C(C)(C)c3ccccc3-4)c3ccc4c(c3)C(c3ccccc3)(c3ccccc3)c3ccccc3-4)cc21] |
| Hole doping material PD | 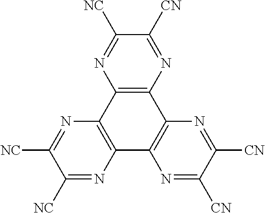 |

Materials of anode 100 in structure 1 to structure 4 and comparative structure 1 are the same, materials of cathode 200 in structure 1 to structure 4 and comparative structure 1 are the same, materials of first hole transport layer HTL1 in structure 1 to structure 4 and comparative structure 1 are the same, materials of first hole block layer HBL1 in structure 1 to structure 4 and comparative structure 1 are the same, materials of first electron transport layer ETL1 in structure 1 to structure 4 and comparative structure 1 are the same, and materials of first electron injection layer EIL1 in structure 1 to structure 4 and comparative structure 1 are the same.

Table 2 shows the data of physical properties of related materials in structure 1 to structure 4 and comparative structure 1.

TABLE 2

| | HOMO | LUMO | T1 | Hole mobility @5000 |
|---|---|---|---|---|
| | (eV) | (eV) | (eV) | electric field |
| First P-type host | 5.26 | 2.37 | 2.36 | 8.4 × 10⁻⁴ |
| material RH-P1 | | | | |
| Second P-type host | 5.21 | 2.39 | 2.22 | 9.3 × 10⁻⁵ |
| material RH-P2 | | | | |
| First N-type host | 5.98 | 2.83 | 2.40 | 7.2 × 10⁻⁴ |
| material RH-N1 | | | | |
| Second N-type host | 5.60 | 2.52 | 2.50 | 9.9 × 10⁻⁴ |
| material RH-N2 | | | | |
| First doping | 5.02 | 3.06 | 2.11 | — |
| material RD1 | | | | |
| First electron | 5.48 | 2.41 | 2.32 | 6.6 × 10⁻⁴ |
| block layer EBL1 | | | | |
| Second electron | 5.52 | 2.45 | 2.20 | 8.1 × 10⁻⁶ |
| block layer EBL2 | | | | |
| First hole host | 5.36 | 2.42 | 2.30 | 9.3 × 10⁻⁴ |
| material HT-1 | | | | |
| Second hole host | 5.21 | 2.29 | 2.29 | 6.4 × 10⁻⁷ |
| material HT-2 | | | | |

Table 3 shows the results of comparative experiments of structure 1 to structure 4 and comparative structure 1. Taking the working voltage V, light emitting efficiency Cd/A and working life of structure 1 as 100%, the working voltages V, light emitting efficiencies Cd/A and working lives of structure 2, structure 3, structure 4 and comparative structure 1 are the relative values vs. structure 1. Herein, the working life LT95 represents the time for OLED to decrease from 1000% of initial brightness to 95%. Since the life curve follows the multi-exponential decay model, the life of OLED can be estimated according to LT95, and CIEx and CIEy represent chromaticity coordinates respectively.

TABLE 3

| | | Light | | | | |
|---|---|---|---|---|---|---|
| | | emitting | Working | Effi- | | |
| | Working | effi- | life | ciency | | |
| | voltage | ciency | LT95 | roll-off | CIEx | CIEy |
| Structure 1 | 100% | 100% | 100% | 6.5% | 0.680 | 0.320 |
| Structure 2 | 106% | 102% | 91% | 8.2% | 0.681 | 0.319 |
| Structure 3 | 104% | 99% | 109% | 5.8% | 0.680 | 0.321 |
| Structure 4 | 98% | 104% | 94% | 8.1% | 0.679 | 0.321 |
| Comparative | 112% | 87% | 81% | 14.5% | 0.679 | 0.320 |
| structure 1 | | | | | | |

As shown in Table 3, compared with comparative structure 1, structure 1 to structure 4 have obvious improvements in reducing the working voltage, reducing the efficiency roll-off, improving the light emitting efficiency and prolonging the working life. Therefore, by setting the mass ratio of the first P-type host material and the first N-type host material and the doping ratio of the first doping material, setting the mobility relationships and the energy level relationships of the first P-type host material, the first N-type host material and the first doping material, setting the mobility relationships and the energy level relationships of the first emitting layer, the first hole injection layer and the first electron block layer, and by adopting matching and combination of parameters in different functional layers, the exemplary embodiment of the present disclosure can significantly improve the light emitting efficiency and the working life, etc., and significantly reduce the efficiency roll-off and the working voltage.

Table 4 shows the materials of an electron block layer and an emitting layer in another comparative experiment of an exemplary embodiment of the present disclosure. In this comparative experiment, the light emitting structure layers of structure 5, comparative structure 2 and comparative structure 3 all adopt the structure shown in FIG. 9, which is HIL1/HTL1/EBL1/EML1/HBL1/N-CGL/P-CGL/HTL2/EBL2/EML2/HBL2/ETL2/EIL2, and the corresponding film layers have the same thickness.

TABLE 4

| | First | Second | | |
|---|---|---|---|---|
| | electron | electron | First | Second |
| | block layer | block layer | emitting layer | emitting layer |
| | EBL1 | EBL2 | EML1 | EML2 |
| Structure 5 | EBL1-1 | EBL2-1 | RH-P1-1:RH-N1-1(5:5) | RH-P2-1:RH-N2-1 (5:5) |
| | | | RD1(2%) | RD2(2%) |
| Comparative | EBL1-2 | EBL2-2 | RH-P1-2:RH-N1-2 (5:5) | RH-P2-2:RH-N2-2 (5:5) |
| structure 2 | | | RD1(2%) | RD2(2%) |
| Comparative | EBL1-2 | EBL2-2 | RH-P1-2:RH-N1-2 (5:5) | RH-P2-2:RH-N2-2 (5:5) |
| structure 3 | | | RD1(10%) | RD2(10%) |

As shown in Table 4, the first electron block layer EBL1 of structure 5 adopts a first type of first electron block material EBL1-1, and the second electron block layer EBL2 adopts a first type of second electron block material EBL2-1. The first emitting layer EML1 includes a first type of first P-type host material RH-P1-1, a first type of first N-type host material RH-N1-1 and a first doping material RD1. The mass ratio of the first type of first P-type host material RH-P1-1 and the first type of first N-type host material RH-N1-1 is 5:5, and the doping ratio of the first doping material RD1 is 2%. The second emitting layer EML2 includes a first type of second P-type host material RH-P2-1, a first type of second N-type host material RH-N2-1 and a second doping material RD2. The mass ratio of the first type of second P-type host material RH-P2-1 and the first type of second N-type host material RH-N2-1 is 5:5, and the doping ratio of the second doping material RD2 is 2%.

As shown in Table 4, the first electron block layer EBL1 of comparative structure 2 and comparative structure 3 adopts a second type of first electron block material EBL1-2, and the second electron block layer EBL2 adopts a second type of second electron block material EBL2-2. The first emitting layer EML1 includes a second type of first P-type host material RH-P1-2, a second type of first N-type host material RH-N1-2 and a first doping material RD1. The mass ratio of the second type of first P-type host material RH-P1-2 and the second type of first N-type host material RH-N1-2 is 5:5. The doping ratio of the first doping material RD1 and the second doping material RD2 in comparative structure 2 is 2%, and the doping ratio of the first doping material RD1 and the second doping material RD2 in comparative structure 3 is 10%.

The materials of the electron block layer and the emitting layer in structure 5, comparative structure 2 and comparative structure 3 are, respectively:

| Items | Materials |
|---|---|
| First type of first P-type host material RH-P1-1 | 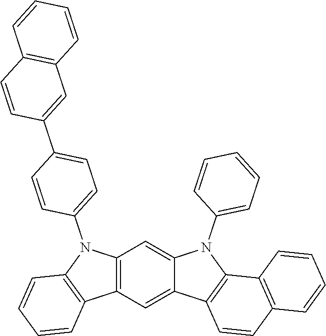 [SMILES: c1ccc(-n2c3cc4c(cc3c3ccc5ccccc5c32)c2ccccc2n4-c2ccc(-c3ccc4ccccc4c3)cc2)cc1] |
| First type of second P-type host material RH-P2-1 | 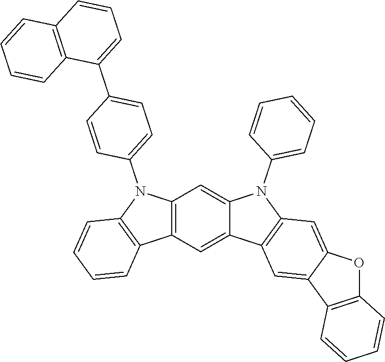 [SMILES: c1ccc(-n2c3cc4oc5ccccc5c4cc3c3cc4c5ccccc5n(-c5ccc(-c6cccc7ccccc67)cc5)c4cc32)cc1] |
| First type of first N-type host material RH-N1-1 | 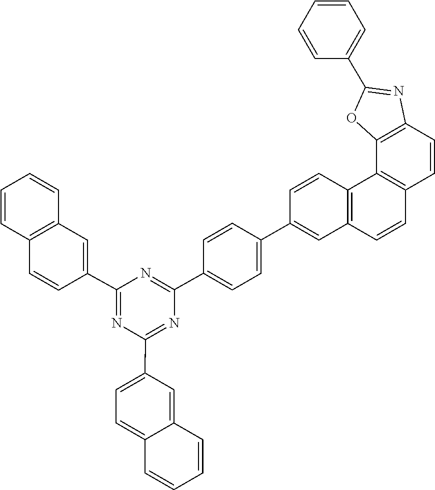 [SMILES: c1ccc(-c2nc3ccc4ccc5cc(-c6ccc(-c7nc(-c8ccc9ccccc9c8)nc(-c8ccc9ccccc9c8)n7)cc6)ccc5c4c3o2)cc1] |
| First type of second N-type host material RH-N2-1 | 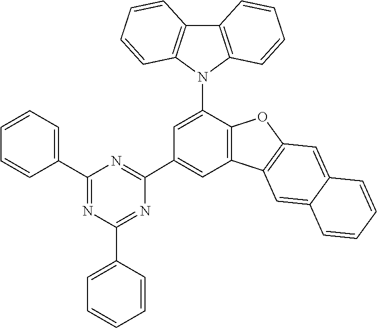 [SMILES: c1ccc(-c2nc(-c3ccccc3)nc(-c3cc(-n4c5ccccc5c5ccccc54)c4oc5cc6ccccc6cc5c4c3)n2)cc1] |
| First type of first electron block layer EBL1-1 | 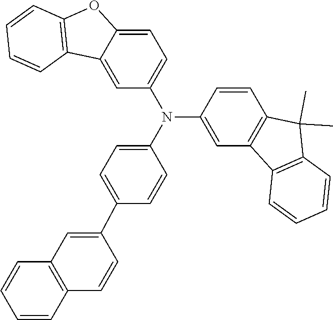 [SMILES: CC1(C)c2ccccc2-c2cc(N(c3ccc(-c4ccc5ccccc5c4)cc3)c3ccc4oc5ccccc5c4c3)ccc21] |
| First type of second electron block layer EBL2-1 | 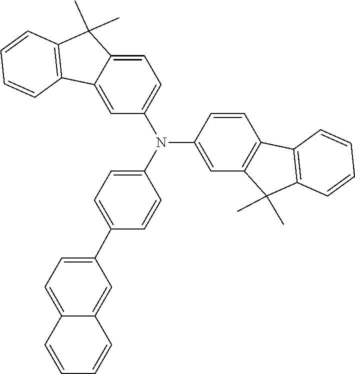 [SMILES: CC1(C)c2ccccc2-c2cc(N(c3ccc(-c4ccc5ccccc5c4)cc3)c3ccc4c(c3)C(C)(C)c3ccccc3-4)ccc21] |
| Second type of first P-type host material RH-P1-2 | 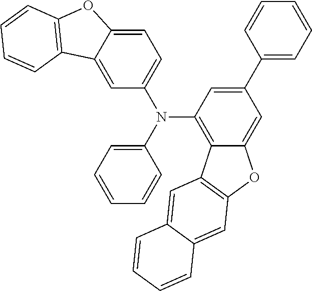 [SMILES: c1ccc(-c2cc(N(c3ccccc3)c3ccc4oc5ccccc5c4c3)c3c(c2)oc2cc4ccccc4cc23)cc1] |
| Second type of second P-type host material RH-P2-2 | 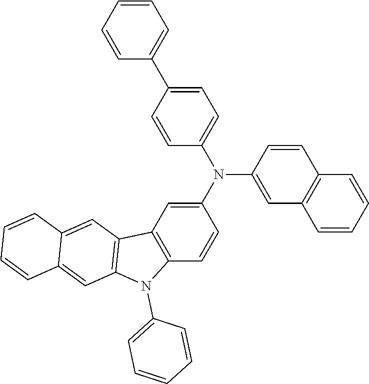 [SMILES: c1ccc(-c2ccc(N(c3ccc4ccccc4c3)c3ccc4c(c3)c3cc5ccccc5cc3n4-c3ccccc3)cc2)cc1] |
| Second type of first N-type host material RH-N1-2 | 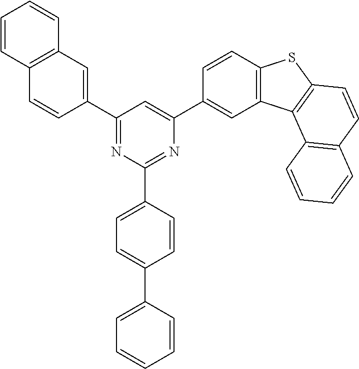 [SMILES: c1ccc(-c2ccc(-c3nc(-c4ccc5ccccc5c4)cc(-c4ccc5sc6ccc7ccccc7c6c5c4)n3)cc2)cc1] |
| Second type of second N-type host material RH-N2-2 | 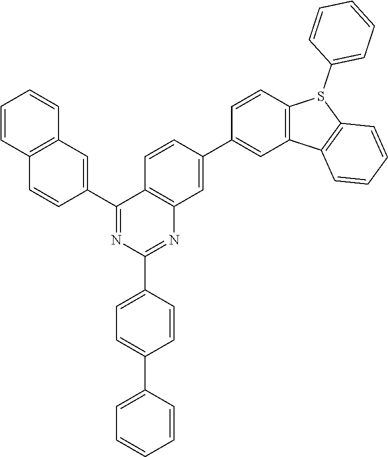 |
| Second type of first electron block layer EBL1-2 | 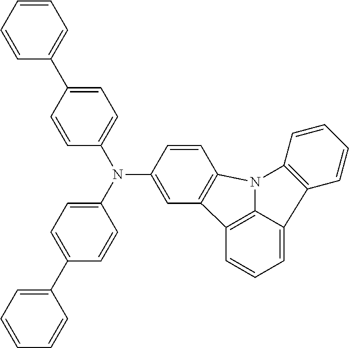 [SMILES: c1ccc(-c2ccc(N(c3ccc(-c4ccccc4)cc3)c3ccc4c(c3)c3cccc5c6ccccc6n4c53)cc2)cc1] |
| Second type of second electron block layer EBL2-2 | 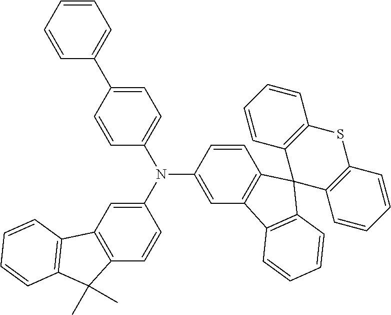 [SMILES: CC1(C)c2ccccc2-c2cc(N(c3ccc(-c4ccccc4)cc3)c3ccc4c(c3)-c3ccccc3C43c4ccccc4Sc4ccccc43)ccc21] |
| First doping material RD1 and second doping material RD2 | 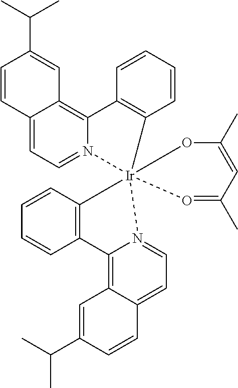 |

| Items | Materials |
|---|---|
| First hole injection layer HIL1 | 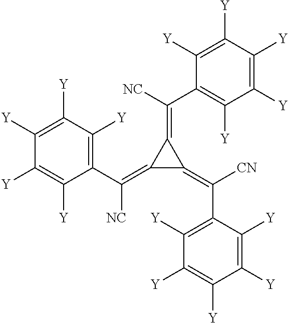 |
| First hole transport layer HTL1 | 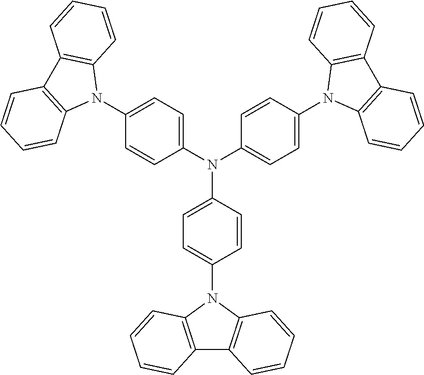 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] |
| First hole block layer HBL1 | 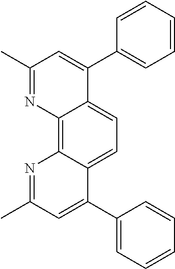 [SMILES: Cc1cc(-c2ccccc2)c2ccc3c(-c4ccccc4)cc(C)nc3c2n1] |
| Electron generation layer N-CGL | 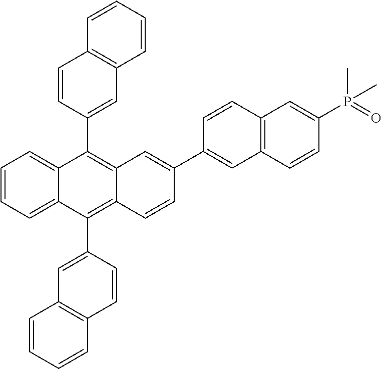 [SMILES: CP(C)(=O)c1ccc2cc(-c3ccc4c(-c5ccc6ccccc6c5)c5ccccc5c(-c5ccc6ccccc6c5)c4c3)ccc2c1] |
| Hole generation layer P-CGL | 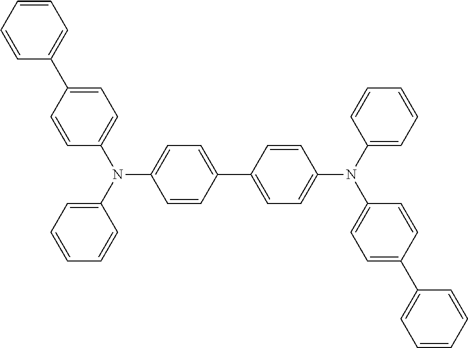 [SMILES: c1ccc(-c2ccc(N(c3ccccc3)c3ccc(-c4ccc(N(c5ccccc5)c5ccc(-c6ccccc6)cc5)cc4)cc3)cc2)cc1] |
| Second hole transport layer HTL2 | 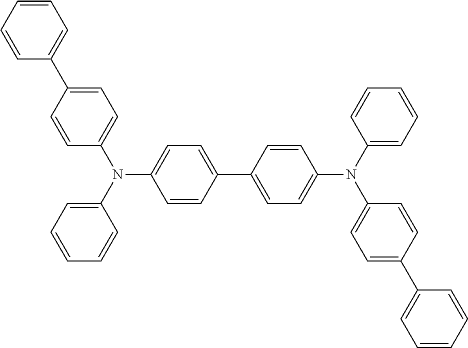 [SMILES: c1ccc(-c2ccc(N(c3ccccc3)c3ccc(-c4ccc(N(c5ccccc5)c5ccc(-c6ccccc6)cc5)cc4)cc3)cc2)cc1] |
| Second hole block layer HBL2 | 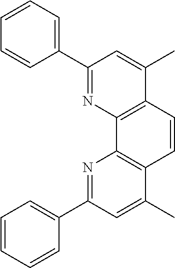 [SMILES: Cc1cc(-c2ccccc2)nc2c1ccc1c(C)cc(-c3ccccc3)nc12] |
| Second electron transport layer ETL2 | 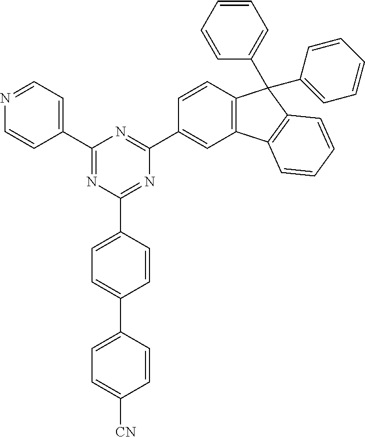 [SMILES: N#Cc1ccc(-c2ccc(-c3nc(-c4ccncc4)nc(-c4ccc5c(c4)-c4ccccc4C5(c4ccccc4)c4ccccc4)n3)cc2)cc1] |
| Second electron | Metallic ytterbium (Yb) |
| injection layer | |
| EIL2 | |

In an exemplary implementation, the electron generation layer N-CGL may be doped with 1% of Li, and the hole generation layer P-CGL may be doped with 5% of PD.

Table 5 shows the data of physical properties of related materials in structure 5, comparative structure 2 and comparative structure 3.

TABLE 5

| | | | Hole mobility | Electron mobility | |
|---|---|---|---|---|---|
| | HOMO | LUMO | @5000 electric | @5000 electric | T1 |
| | (eV) | (eV) | field | field | (eV) |
| RH-P1-1 | 5.31 | 2.38 | 6.4 × 10⁻⁵ | | 2.36 |
| RH-P1-2 | 5.42 | 2.43 | 9.2 × 10⁻⁶ | | 2.31 |
| RH-N1-1 | 5.86 | 2.74 | — | 5.5 × 10⁻⁵ | 2.34 |
| RH-N1-2 | 5.96 | 2.84 | — | 8.8 × 10⁻⁷ | 2.35 |
| RH-P2-1 | 5.32 | 2.36 | 5.4 × 10⁻⁵ | | 2.34 |
| RH-P2-2 | 5.44 | 2.51 | 4.4 × 10⁻⁶ | | 2.31 |
| RH-N2-1 | 5.93 | 2.81 | — | 5.8 × 10⁻⁵ | 2.38 |
| RH-N2-2 | 5.92 | 2.82 | — | 8.0 × 10⁻⁷ | 2.35 |
| EBL1-1 | 5.54 | 2.31 | 1.9 × 10⁻⁵ | | 2.43 |
| EBL1-2 | 5.36 | 2.22 | 5.9 × 10⁻⁵ | | 2.31 |
| EBL2-1 | 5.50 | 2.34 | 3.1 × 10⁻⁵ | | 2.41 |
| EBL2-2 | 5.30 | 2.35 | 4.2 × 10⁻⁵ | | 2.34 |
| RD1 and | 5.08 | 2.95 | — | — | 2.14 |
| RD2 | | | | | |

Table 6 shows the mobility data of the first emitting layer and the second emitting layer in structure 5, comparative structure 2 and comparative structure 3.

TABLE 6

| | Hole mobility | Electron mobility |
|---|---|---|
| | @5000 electric | @5000 electric |
| | field | field |
| First emitting layer of structure 5 | 1.2 × 10⁻⁶ | 4.3 × 10⁻⁵ |
| RH-P1-1:RH-N1-1(5:5):RD1(2%) | | |
| Second emitting layer of structure 5 | 2.1 × 10⁻⁶ | 3.9 × 10⁻⁵ |
| RH-P2-1:RH-N2-1 (5:5):RD2(2%) | | |
| First emitting layer of | 7.4 × 10⁻⁷ | 7.6 × 10⁻⁷ |
| comparative structure 2 | | |
| RH-P1-2:RH-N1-2 (5:5):RD1(2%) | | |
| Second emitting layer of | 6.4 × 10⁻⁷ | 6.9 × 10⁻⁷ |
| comparative structure 2 | | |
| RH-P2-2:RH-N2-2 (5:5):RD2(2%) | | |
| First emitting layer of | 2.6 × 10⁻⁸ | 1.6 × 10⁻⁷ |
| comparative structure 3 | | |
| RH-P1-2:RH-N1-2 (5:5):RD1(10%) | | |
| Second emitting layer of | 7.1 × 10⁻⁸ | 2.2 × 10⁻⁷ |
| comparative structure 3 | | |
| RH-P2-2:RH-N2-2 (5:5):RD2(10%) | | |

Table 7 shows the results of comparative experiments of structure 5, comparative structure 2 and comparative structure 3. Taking the working voltage V, light emitting efficiency Cd/A and working life of structure 5 as 100%, the working voltages V, light emitting efficiencies Cd/A and working lives of comparative structure 2 and comparative structure 3 are the relative values v.s. structure 5.

TABLE 7

| | | Light | | | | |
|---|---|---|---|---|---|---|
| | | emitting | | | | Effi- |
| | Working | effi- | | | Working | ciency |
| | voltage | ciency | CIEx | CIEy | life LT95 | roll-off |
| Structure 5 | 100% | 100% | 0.682 | 0.320 | 100% | 11% |
| Comparative | 103% | 96% | 0.682 | 0.320 | 92% | 15% |
| structure 2 | | | | | | |
| Comparative | 109% | 92% | 0.682 | 0.320 | 86% | 25% |
| structure 3 | | | | | | |

As shown in Table 7, compared with comparative structure 2 and comparative structure 3, structure 5 have obvious improvements in reducing the working voltage, reducing the efficiency roll-off, improving the light emitting efficiency and prolonging the working life. Therefore, by setting the mass ratios of the P-type host material and the N-type host material and the doping ratios of the doping material in the first emitting layer and the second emitting layer, setting the mobility relationships and the energy level relationships of the P-type host material, the N-type host material and the doping material, setting the mobility relationship and the energy level relationship of the first emitting layer and the second emitting layer, setting the mobility relationship and the energy level relationship of the emitting layer and the electron block layer, and by adopting matching and combination of parameters in different functional layers, the exemplary embodiments of the present disclosure effectively improve the hole-electron balance in different emitting layers, reduce the efficiency roll-off and working voltage, and improve light emitting efficiency and working life.

As shown in Table 6, in structure 5, the ratio of electron mobility to hole mobility in the first emitting layer is about 35.8, the ratio of electron mobility to hole mobility in the second emitting layer is about 18.6, the ratio of hole mobility in the second emitting layer to hole mobility in the first emitting layer is about 1.1, and the ratio of electron mobility in the first emitting layer to electron mobility in the second emitting layer is about 1.1. In comparative structure 2, the ratio of electron mobility to hole mobility in the first emitting layer is about 1, the ratio of electron mobility to hole mobility in the second emitting layer is about 1, the ratio of hole mobility in the second emitting layer to hole mobility in the first emitting layer is about 0.86, and the ratio of electron mobility in the first emitting layer to electron mobility in the second emitting layer is about 1.1. In comparative structure 3, the ratio of electron mobility to hole mobility in the first emitting layer is about 6, the ratio of electron mobility to hole mobility in the second emitting layer is about 3, the ratio of hole mobility in the second emitting layer to hole mobility in the first emitting layer is about 2.7, and the ratio of electron mobility in the first emitting layer to electron mobility in the second emitting layer is about 0.7.

As can be seen from the comparison results in Table 7, by setting the hole mobility of the second emitting layer greater than that of the first emitting layer and the electron mobility of the first emitting layer greater than that of the second emitting layer, that is, increasing the ratio of electron mobility to hole mobility in the first emitting layer and the second emitting layer, the present disclosure can make the hole mobility of the second emitting layer faster and the electron mobility slower relative to the first emitting layer, and compensate the problem of weak capability of generating hole charges of the hole generation layer P-CGL, thereby reducing the efficiency roll-off and working voltage, and improving the light emitting efficiency and working life.

According to the comparison results in Table 7, it can be seen that structure 5 satisfies the mobility relationship of the first emitting layer EML1 and the second emitting layer EML2, that is, structure 5 satisfies:

$$10 \leq μ e ( EML 1 ) / μ h ( EML 1 ) \leq 5 \; 000 ;$$

$$10 \leq μ e ( EML 2 ) / μ h ( EML 2 ) \leq 5 \; 000 ;$$

$$1 \leq μ h ( EML 2 ) / μ h ( EML 1 ) \leq 100 ;$$

$$1 \leq μ e ( EML 1 ) / μ e ( EML 2 ) \leq 100 .$$

In contrast, comparative structure 2 and comparative structure 3 do not satisfy three of them, and therefore, compared with comparative structure 5, the performances of comparative structure 2 and comparative structure 3, such as efficiency roll-off, working voltage, light emitting efficiency and working life, are decreased.

FIG. 10 is a comparison result of efficiency curves of structure 5, comparative structure 2 and comparative structure 3. As shown in FIG. 10, the efficiency roll-off of structure 5 is significantly reduced compared with comparative structure 2 and comparative structure 3. When the current density is 15 mA/cm², the light emitting efficiency of structure 5 can still reach 90%, while the light emitting efficiency of comparative structure 3 is lower than 80%.

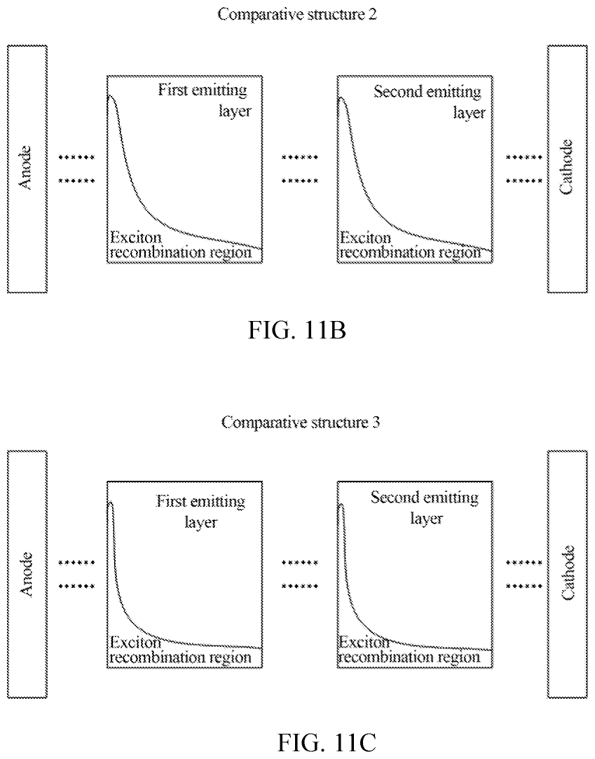

FIG. 11A, FIG. 11B, and FIG. 11C illustrate schematic diagrams of exciton recombination regions of structure 5, comparative structure 2, and comparative structure 3, respectively. As shown in FIG. 11A, FIG. 11B, and FIG. 11C, the exciton recombination region of structure 5 is clearly closer to the center of the emitting layer than that of comparative structure 2 and comparative structure 3, so that the exciton recombination regions of the first emitting layer and the second emitting layer are more balanced, and the triplet exciton annihilation and triplet exciton-polaron quenching effects are reduced, thereby reducing the efficiency roll-off, which can not only improve the display brightness, but also can prolong the working life.

The present disclosure further provides a display apparatus, including the foregoing organic light emitting device. The display apparatus may be any product or component with a display function, such as a mobile phone, a tablet computer, a television, a display, a notebook computer, a digital photo frame, a navigator, a vehicle-mounted display, a smart watch or a smart bracelet.

Although the implementations of the present disclosure are disclosed above, the contents are only implementations used for ease of understanding of the present disclosure, but not intended to limit the present disclosure. Any skilled person in the art to which the present disclosure pertains may make any modifications and alterations in forms and details of implementation without departing from the spirit and scope of the present disclosure. However, the patent protection scope of the present disclosure should be subject to the scope defined by the appended claims.

1. An organic light emitting device comprising an anode, a cathode and a light emitting structure layer disposed between the anode and the cathode, wherein, the light emitting structure layer comprises at least a first emitting layer, the first emitting layer comprises a first P-type host material, a first N-type host material and a first doping material, the mass ratio of the first P-type host material to the first N-type host material is 3:7 to 7:3, the mass of the first doping material is 1% to 5% of the mass of the first host material, and the mass of the first host material is the sum of the masses of the first P-type host material and the first N-type host material.

2. The organic light emitting device according to claim 1, wherein, the first P-type host material and the first N-type host material satisfy:
$$0.1 \leq μ e ( RH - N 1 ) / μ h ( RH - P 1 ) \leq 1 \; 000 ;$$
wherein, μe(RH-N1) is the electron mobility of the first N-type host material, and μh(RH-P1) is the hole mobility of the first P-type host material.

3. The organic light emitting device according to claim 1, wherein, the first P-type host material and the first N-type host material satisfy:
$$0.4 eV \leq \vert HOMO ( RH - N 1 ) \vert - \vert HOMO ( RH - P 1 ) \vert \leq 1. eV ;$$
$$0.3 eV \leq \vert LUMO ( RH - N 1 ) \vert - \vert LUMO ( RH - P 1 ) \vert \leq 0.7 eV ;$$
wherein, HOMO(RH-N1) is the HOMO energy level of the first N-type host material, HOMO(RH-P1) is the HOMO energy level of the first P-type host material, LUMO(RH-N1) is the LUMO energy level of the first N-type host material, and LUMO(RH-P1) is the LUMO energy level of the first P-type host material.

4. The organic light emitting device according to claim 1, wherein, the first P-type host material and the first doping material satisfy:
$$0.2 eV \leq \vert HOMO ( RH - P 1 ) \vert - \vert HOMO ( RD 1 ) \vert \leq 0.5 eV ;$$
$$0.2 eV \leq T 1 ( RH - P 1 ) - T 1 ( RD 1 ) \leq 0.5 eV ;$$
wherein, HOMO(RH-P1) is the HOMO energy level of the first P-type host material, HOMO(RD1) is the HOMO energy level of the first doping material, T1(RH-P1) is the lowest triplet energy level of the first P-type host material, and T1(RD1) is the lowest triplet energy level of the first doping material.

5. The organic light emitting device according to claim 1, wherein, the first N-type host material and the first doping material satisfy:
$$2 eV \leq \vert LUMO ( RD 1 ) \vert - \vert LUMO ( RH - N 1 ) \vert \leq 0.5 eV ;$$
$$0.2 eV \leq T 1 ( RH - N 1 ) - T 1 ( RD 1 ) \leq 0.5 eV ;$$
wherein, LUMO(RH-N1) is the LUMO energy level of the first N-type host material, LUMO(RD1) is the LUMO energy level of the first doping material, T1(RH-N1) is the lowest triplet energy level of the first N-type host material, and T1(RD1) is the lowest triplet energy level of the first doping material.

6. The organic light emitting device according to claim 1, wherein, the light emitting structure layer further comprises a first electron block layer disposed between the anode and the first emitting layer, and the first P-type host material and the first electron block layer satisfy:
$$0 \leq \vert HOMO ( EBL 1 ) \vert - \vert HOMO ( RH - P 1 ) \vert \leq 0.3 eV ;$$
$$0.1 \leq μ h ( RH - P 1 ) / μ h ( EBL 1 ) \leq 100 ;$$
wherein, HOMO(EBL1) is the HOMO energy level of the first electron block layer, HOMO(RH-P1) is the HOMO energy level of the first P-type host material, μh(RH-P1) is the hole mobility of the first P-type host material, and μh(EBL1) is the hole mobility of the first electron block layer.

7. The organic light emitting device according to claim 6, wherein, the first doping material and the first electron block layer satisfy:
$$0.1 eV \leq T 1 ( EBL 1 ) - T 1 ( RD 1 ) \leq 0.5 eV ;$$
wherein, T1(EBL1) is the lowest triplet energy level of the first electron block layer, and T1(RD1) is the lowest triplet energy level of the first doping material.

8. The organic light emitting device according to claim 6, wherein, the light emitting structure layer further comprises a first hole injection layer disposed between the anode and the first electron block layer, and the first hole injection layer and the first electron block layer satisfy:
$$0 \leq \vert HOMO ( EBL 1 ) \vert - HOMO ( HIL 1 ) \vert \leq 0.3 eV ;$$
$$0.1 \leq μ h ( HIL 1 ) / μ h ( EBL 1 ) \leq 100 ;$$
wherein, HOMO(HIL1) is the HOMO energy level of the first hole injection layer, and μh(HIL1) is the hole mobility of the first hole injection layer.

9. The organic light emitting device according to claim 8, wherein, the first hole injection layer comprises a hole host material and a hole doping material, and the mass of the hole doping material is 1.5% to 4.5% of the mass of the hole host material.

10. The organic light emitting device according to claim 1, wherein, the light emitting structure layer further comprises a charge generation layer and a second emitting layer, the first emitting layer is disposed between the anode and the charge generation layer, and the second emitting layer is disposed between the charge generation layer and the cathode; the second emitting layer comprises a second P-type host material, a second N-type host material and a second doping material, the mass ratio of the second P-type host material to the second N-type host material is 3:7 to 7:3, the mass of the second doping material is 1% to 5% of the mass of the second host material, and the mass of the second host material is the sum of the masses of the second P-type host material and the second N-type host material.

11. The organic light emitting device according to claim 10, wherein, the second P-type host material and the second N-type host material satisfy:
$$0.1 \leq μe ( RH - N 2 ) / μ h ( RH - P 2 ) \leq 1 \; 000 ;$$
wherein, μe(RH-N2) is the electron mobility of the second N-type host material, and μh(RH-P2) is the hole mobility of the second P-type host material.

12. The organic light emitting device according to claim 10, wherein, the second P-type host material and the second N-type host material satisfy:
$$0.4 eV \leq \vert HOMO ( RH - N 2 ) \vert - \vert HOMO ( RH - P 2 ) \vert \leq 1. eV ;$$
$$0.3 eV \leq \vert LUMO ( RH - N 2 ) \vert - \vert LUMO ( RH - P 2 ) \vert \leq 0.7 eV ;$$
wherein, HOMO(RH-N2) is the HOMO energy level of the second N-type host material, HOMO(RH-P2) is the HOMO energy level of the second P-type host material, LUMO(RH-N2) is the LUMO energy level of the second N-type host material, and LUMO(RH-P2) is the LUMO energy level of the second P-type host material.

13. The organic light emitting device according to claim 10, wherein, the second P-type host material, the second N-type host material and the second doping material satisfy:
$$0.2 eV \leq \vert HOMO ( RH - P 2 ) \vert - \vert HOMO ( RD 2 ) \vert \leq 0.5 eV ;$$
$$0.2 eV \leq \vert LUMO ( RD 2 ) \vert - \vert LUMO ( RH - N 2 ) \vert \leq 0.5 eV ;$$
wherein, HOMO(RH-P2) is the HOMO energy level of the second P-type host material, HOMO(RD2) is the HOMO energy level of the second doping material, LUMO(RH-N2) is the LUMO energy level of the second N-type host material, and LUMO(RD2) is the LUMO energy level of the second doping material.

14. The organic light emitting device according to claim 10, wherein, the first P-type host material and the second P-type host material satisfy:
$$1 \leq μh ( RH - P 2 ) / μ h ( RH - P 1 ) \leq 100 ;$$
wherein, μh(RH-P1) is the hole mobility of the first P-type host material, and μh(RH-P2) is the hole mobility of the second P-type host material,
or, the first P-type host material and the second P-type host material satisfy:
$$HOMO ( RH - P 1 ) \leq HOMO ( RH - P 2 ) ;$$
wherein, HOMO(RH-P1) is the HOMO energy level of the first P-type host material, and HOMO(RH-P2) is the HOMO energy level of the second P-type host material.

15. The organic light emitting device according to claim 10, wherein, the first N-type host material and the second N-type host material satisfy:
$$1 \leq μe ( RH - N 1 ) / μ e ( RH - N 2 ) \leq 100 ;$$
wherein, μe(RH-N1) is the electron mobility of the first N-type host material, and μe(RH-N2) is the electron mobility of the second N-type host material,
or, the first N-type host material and the second N-type host material satisfy:
$$LUMO ( RH - N 1 ) \leq LUMO ( RH - N 2 ) ;$$
wherein, LUMO(RH-N1) is the LUMO energy level of the first N-type host material, and LUMO(RH-N2) is the LUMO energy level of the second N-type host material.

16. (canceled)

17. (canceled)

18. The organic light emitting device according to claim 10, wherein, the first emitting layer and the second emitting layer satisfy:
$$10 \leq μ e ( EML 1 ) / μ h ( EML 1 ) \leq 5000 ;$$
$$10 \leq μ e ( EML 2 ) / μ h ( EML 2 ) \leq 5000 ;$$
$$1 \leq μ h ( EML 2 ) / μ h ( EML 1 ) \leq 100 ;$$
$$1 \leq μ e ( EML 1 ) / μ e ( EML 2 ) \leq 100 ;$$
wherein, μe(EML1) is the electron mobility of the first emitting layer, μe(EML2) is the electron mobility of the second emitting layer, μh(EML1) is the hole mobility of the first emitting layer, and μh(EML2) is the hole mobility of the second emitting layer.

19. The organic light emitting device according to claim 10, wherein, the light emitting structure layer further comprises a first electron block layer disposed between the anode and the first emitting layer and a second electron block layer disposed between the charge generation layer and the second emitting layer, and the first electron block layer and the second electron block layer satisfy:
$$1 \leq μ h ( EBL 2 ) / μ h ( EBL 1 ) \leq 100 ;$$
wherein, μh(EBL1) is the hole mobility of the first electron block layer, and μh(EBL2) is the hole mobility of the second electron block layer.

20. The organic light emitting device according to claim 19, wherein, the first electron block layer, the first emitting layer, the second electron block layer, and the second emitting layer satisfy:
$$HOMO ( RH - N 1 ) < HOMO ( EBL 1 ) < HOMO ( RH - P 1 ) ;$$
$$HOMO ( RH - N 2 ) < HOMO ( EBL 2 ) < HOMO ( RH - P 2 ) ;$$
wherein, HOMO(RH-N1) and HOMO(RH-N2) are the HOMO energy levels of the first N-type host material and the second N-type host material, respectively, HOMO(RH-P1) and HOMO(RH-P2) are the HOMO energy levels of the first P-type host material and the second P-type host material, respectively, and HOMO(EBL1) and HOMO(EBL2) are the HOMO energy levels of the first electron block layer and the second electron block layer, respectively.

21. The organic light emitting device according to claim 19, wherein, the first electron block layer, the first emitting layer, the second electron block layer, and the second emitting layer satisfy:
$$T 1 ( RD 1 ) < T 1 ( RH - P 1 ) < T 1 ( EBL 1 ) ;$$
$$T 1 ( RD 2 ) < T 1 ( RH - P 2 ) < T 1 ( EBL 2 ) ;$$
$$T 1 ( RD 1 ) < T 1 ( RH - N 1 ) < T 1 ( EBL 1 ) ;$$
$$T 1 ( RD 2 ) < T 1 ( RH - N 2 ) < T 1 ( EBL 2 ) ;$$
wherein, T1(RH-N1) and T1(RH-N2) are the lowest triplet energy levels of the first N-type host material and the second N-type host material, respectively, T1(RH-P1) and T1(RH-P2) are the lowest triplet energy levels of the first P-type host material and the second P-type host material, respectively, T1(RD1) and T1 (RD2) are the lowest triplet energy levels of the first doping material and the second doping material, respectively, and T1(EBL1) and T1(EBL2) are the lowest triplet energy levels of the first electron block layer and the second electron block layer, respectively.

22. A display apparatus, comprising the organic light emitting device according to claim 1.
